(19) United States
(12) Patent Application Publication
(10) Pub. No.: US 2026/0016619 A1
(43) Pub. Date: Jan. 15, 2026

(54) OPTICAL DEVICE, IMAGE SENSOR, AND METHOD FOR MANUFACTURING OPTICAL DEVICE

(71) Applicant: Nippon Sheet Glass Company, Limited, Tokyo (JP)

(72) Inventors: Hiroaki KATO, Kanagawa (JP); Shigeo KITTAKA, Hyogo (JP)

(21) Appl. No.: 18/881,133

(22) PCT Filed: Jan. 18, 2023
(86) PCT No.: PCT/JP2023/001412

§ 371 Date: Jan. 3, 2025

(30) Foreign Application Priority Data
Jul. 4, 2022 (JP) 2022-107966

(51) Int. Cl. G02B 3/00

(52) U.S. Cl. CPC G02B 3/0037

(57) ABSTRACT

An optical device 1a includes a lens array 10 and a transparent dielectric array 20. The lens array 10 includes a plurality of lenses 11. In the lens array 10, the lenses 11 are arrayed such that the optical axes thereof are substantially parallel to each other. The transparent dielectric array 20 includes a plurality of transparent dielectrics 21. In the transparent dielectric array 20, the transparent dielectrics 21 are arrayed such that the central axes thereof are substantially parallel to each other. The lens array 10 and the transparent dielectric array 20 are arranged such that the optical axes of the lenses 11 and the central axes of the transparent dielectrics 21 are substantially parallel to each other, and that an end surface of the lens array 10 and an end surface of the transparent dielectric array 20 face each other.

### TECHNICAL FIELD

The present invention relates to an optical device, an image sensor, and a method for manufacturing an optical device.

### BACKGROUND ART

A conventionally known lens array is formed by aligning a plurality of lenses in a predetermined direction and integrating the lenses such that their optical axes or their central axes will be parallel to each other. Even if such a lens array is small, formation of an image by overlapping images obtained by individual single lenses makes it possible to obtain image information on an object plane as two-dimensional image information. Taking advantage of the characteristics and functions, the lens array is used in an image sensor together with an illuminator and a light receiving element array such as a photodiode (PD) array. Examples of the image sensor where the lens array is used include a contact image sensor (CIS).

Compared to reduced optical imaging scanners equipped with two-dimensional sensors such as a Charge-Coupled Device (CCD) and a Complementary Metal-Oxide Semiconductor (CMOS), a plurality of lenses, and a mirror, an image sensor including a lens array has advantages, for example, a distance between an object and a light receiving element (imaging element), a distance between an object point and an image point, or a distance between an object plane and an image plane, is short to easily save a space, a small number of parts thereof results in favorable maintainability, and ease of assembly.

A lens array used in a device such as a contact image sensor has advantages such as compactness and cost reduction. Furthermore, the lens array can easily provide high resolution and high-contrast images. On the other hand, the depth of field of the lens array tends to be small. As a result, the image quality may deteriorate, for example, when capturing an image of a subject with a large unevenness, such as a spread of a book or a photograph protected in a transparent case, or a subject located far from a document platen.

For example, Patent Literature 1 describes a method for improving this depth of field, which involves placing an overlap-limiting member having a plurality of apertures corresponding to a plurality of lens elements in the lens array. The optical axis of each lens element in the lens array aligns with the center of the aperture. It is considered that in this method, the overlap-limiting member is not capable of narrowing the imaging field of the lens unless the optical axis of the lens element aligns with the center of the aperture of the overlap-limiting member, and as a result, image overlapping cannot be reduced. In the meantime, in production of a lens array, it is considered difficult to array a plurality of lens elements precisely in an ideal array.

Patent Literature 2 describes a method for disposing a light-shielding mask having a diffraction effect on a plane positioned between a document surface and a light receiving element array and perpendicular to the optical axis of the lens array in a contact image sensor. This method is thought to cause a problem, namely, high-frequency components, which are important from the view of fine resolution, are not easily reflected in the image.

### CITATION LIST

### Patent Literature

Patent Literature 1: JP H06-342131 A
Patent Literature 2: JP H10-173862 A

### SUMMARY OF INVENTION

### Technical Problem

In view of such circumstances, the present invention provides an optical device that is advantageous from the viewpoint of capturing images with high resolution, even for subjects with unevenness and height differences.

### Solution to Problem

The present invention provides an optical device including:
a lens array including a plurality of lenses, where the lenses are arrayed such that optical axes of the lenses are substantially parallel to each other; and
a transparent dielectric array including a plurality of transparent dielectrics, where the transparent dielectrics are arrayed such that central axes of the transparent dielectrics are substantially parallel to each other,
wherein the lens array and the transparent dielectric array are arranged such that the optical axes and the central axes are substantially parallel to each other and an end surface of the lens array faces an end surface of the transparent dielectric array.

The present invention further provides an image sensor including the aforementioned optical device.

### Advantageous Effects of Invention

The above-mentioned optical device is advantageous from the viewpoint of capturing images with high resolution even for a subject with unevenness and height differences. The above-mentioned optical device is also advantageous in that it has a relatively large depth of field compared to a case of using the lens array alone.

### BRIEF DESCRIPTION OF DRAWINGS

FIG. 1 is a perspective view showing an example of an optical device according to the present invention.

FIG. 2 is a schematic perspective view showing an example of a lens array related to the present invention.

FIG. 3 is a diagram showing a relation between an object plane and an image plane of a lens array.

FIG. 4 is a diagram showing an image formation by a rod lens with a refractive index distribution.

FIG. 5A is a diagram showing an imaging state of two adjacent rod lenses when an object is at a conjugate position.

FIG. 5B is a diagram showing an imaging state of two adjacent rod lenses when an object is misaligned from a conjugate position.

FIG. 6 is a diagram schematically showing a spread of beams that can be received at a position away by a distance r from the central axis on the light-incident surface of a rod lens.

FIG. 7 is a graph showing schematically a relation between an angle θ, which is determined from a definition of an aperture of the rod lens, and the distance r from the central axis.

FIG. 8A is a diagram schematically showing a spread of beams in the absence of a transparent dielectric array.

FIG. 8B is a diagram schematically showing a limitation of field of vision in the case where a transparent dielectric is arranged in the optical axis direction of a rod lens.

FIG. 8C is a diagram schematically showing a limitation of field of vision in the case where a transparent dielectric is arranged in the optical axis direction of the rod lens.

FIG. 8D is a diagram schematically showing a limitation of field of vision in the case where a transparent dielectric is arranged in the optical axis direction of the rod lens.

FIG. 9 is a perspective view showing an example of a transparent dielectric array according to the present invention.

FIG. 10A is a diagram showing an optical system including a rod lens array.

FIG. 10B is a diagram showing an optical system including a rod lens array.

FIG. 10C is a diagram showing an optical system including a rod lens array and a transparent dielectric array.

FIG. 10D is a diagram showing an optical system including a rod lens array and a transparent dielectric array.

FIG. 11 is a graph showing a relation between a ratio rmsᵣ of a root mean square of a ray aberration and P₁/P₀ in the optical system including a rod lens array and a transparent dielectric array.

FIG. 12A is a graph showing a relation between a ratio rmsᵣ of a ray aberration rms and H/(n₁·L₀₁) in an optical system including a rod lens array a and a transparent dielectric array.

FIG. 12B is a graph showing a relation between a ratio rmsᵣ of a ray aberration rms and H/(n₁·L₀₁) in an optical system including a rod lens array β and a transparent dielectric array.

FIG. 12C is a graph showing a relation between a ratio rmsᵣ of a ray aberration rms and H/(n₁·L₀₁) in an optical system including a rod lens array γ and a transparent dielectric array.

FIG. 13 is a graph showing a relation between H/(n₁·L₀₁)th and P₁/P₀ in an optical system including a lens α, β, or γ and a transparent dielectric array.

FIG. 14 is a graph showing a relation between irradiance unevenness ΔI and H/(n₁·L₀₁) in an optical system including a lens α, β, or γ and a transparent dielectric array.

FIG. 15A is a diagram showing an example of an image sensor according to the present invention.

FIG. 15B is a diagram showing another example of an image sensor according to the present invention.

FIG. 15C is a diagram showing yet another example of an image sensor according to the present invention.

### DESCRIPTION OF EMBODIMENTS

Embodiments of the present invention will be described below. The following description relates to an example of the present invention, and the present invention is not limited to the following embodiments.

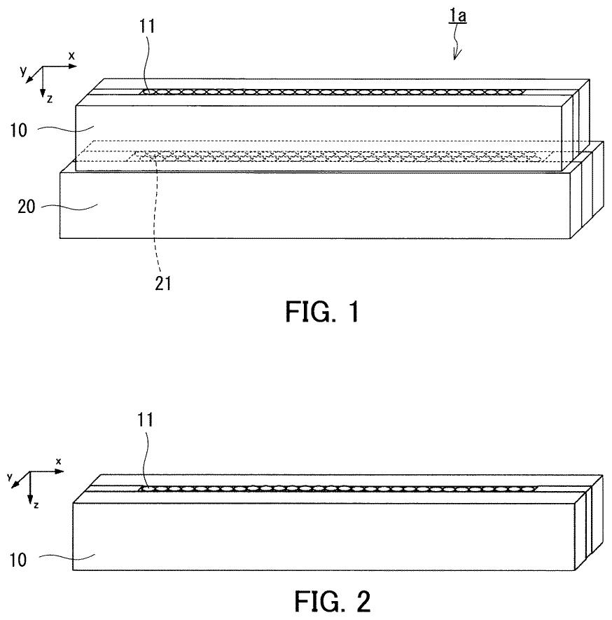

FIG. 1 is a perspective view showing an example of an optical device according to the present invention. As shown in FIG. 1, an optical device 1a includes a lens array 10 and a transparent dielectric array 20. Directions indicated by x, y, and z are the directions of the x-, y-, and z-axes of a Cartesian coordinate system, respectively. The lens array 10 includes a plurality of lenses 11. In the lens array 10, the lenses 11 are arrayed in the x direction only (single-row array) such that their optical axes will be substantially parallel to each other. For example, when observing a plurality of lenses 11 along a direction perpendicular to the optical axis of a particular lens 11, the optical axis of the particular lens 11 is substantially parallel to the optical axes of the other lenses 11. The transparent dielectric array 20 includes a plurality of transparent dielectrics 21. In the transparent dielectric array 20, the transparent dielectrics 21 are arrayed in the x direction and y direction so that their central axes are substantially parallel to each other. In the transparent dielectric array 20, the transparent dielectrics 21 are arrayed in two rows in the y direction and further a relatively large number of the transparent dielectrics 21 are arrayed in the x direction to make a longer row (double-row array). Specifically, the transparent dielectric array 20 may include two rows of lenses, each of which includes the transparent dielectrics 21 arrayed in a single row, by overlapping the rows in the y direction. For example, when observing a plurality of transparent dielectrics 21 along a direction perpendicular to the central axis of a particular transparent dielectric 21, the central axis of the particular transparent dielectric 21 is substantially parallel to the central axes of the other transparent dielectrics 21. The lens array 10 and transparent dielectric array 20 are arranged such that the optical axes of the lenses 11 and the central axes of the transparent dielectrics 21 will be substantially parallel to each other, and the end surface of the lens array 10 and the end surface of the transparent dielectric array 20 will face each other. By arranging the lens array 10 and the transparent dielectric array 20 in such a way that they are disposed as described above, the optical device 1a is obtained. For example, when the lens array 10 and the transparent dielectric array 20 are observed along a direction perpendicular to the central axes of the transparent dielectrics 21, the optical axes of the lenses 11 extend in a direction parallel to the central axis of the transparent dielectric 21. Here, the expression that a plurality of axes or objects are substantially parallel to each other means that the angle between them is 1° or less.

In a lens array, a plurality of lenses having a light-collecting function can be arrayed one-dimensionally or two-dimensionally such that their central axes or optical axes are substantially parallel. Lens arrays are widely employed for optical systems of devices for capturing images, such as facsimiles, copiers, and printers. End surface-refractive lenses are known as lenses used in lens arrays. In such an end surface-refractive lens, at least one of its light-incident end surface and its light-emitting end surface is curved, and light is collected by the refractive action of the end surface.

In addition, a refractive index distribution type rod lens is also known as a lens to be used in a lens array. A refractive index distribution type rod lens (hereafter, may be simply referred to as a “rod lens”) is a dielectric made of, for example, a cylindrical resin or glass capable of transmitting light, and the rod lens has a refractive index distribution in which the refractive index decreases from the center to the outer circumference. Unlike an end surface-refractive lens, the planes of the rod lens serving for incidence and emission of light may not be curved partly or entirely. Even such a rod lens is capable of exhibiting functions for collecting or diverging light. The rod lens does not require a process of curving the end surfaces, the process will directly increase the manufacturing costs. As a result, this rod lens can be easily made small and can be used as a light-collecting lens for optical communications. In addition, a lens array where the central axes of a plurality of rod lenses are arrayed to be substantially parallel to each other is capable of imaging a linear or planar object onto the light-collecting surface. For this reason, such a lens array has outstanding characteristics such as compactness, cost reduction and high handleability while also demonstrating high optical performance such as high resolution or high contrast. In particular, a lens array with glass rod lenses tends to have significantly high weather resistance and long-term reliability. The technical fields to which such lens arrays can be applied are diverse.

In the lens array 10, each of the lenses 11 is, for example, a rod lens having a refractive index distribution in the radial direction. In this case, the lenses 11 may be made of resin or glass. The lenses 11 may preferably be made of glass. The lenses 11 may be end surface-refractive lenses.

The array of the lenses 11 in the lens array 10 is not limited to any specific aspect. In the lens array 10, the lenses 11 are single lenses having a light-collecting effect, and the lenses 11 are arrayed in at least one direction. The array of the lenses 11 in the lens array 10 may be a one-dimensional array of 1×n (where n is an integer equal to or greater than 2), or a two-dimensional array of m×I (where m and I are integers equal to or greater than 2). The 1×n array may be referred to as a single-row array, a 2×I array may be referred to as a double-row array, and a 3×I array may be referred to as a triple-row array, where m (m=1, 2, 3, . . . ) is referred to as the number of rows. The array of the lenses 11 in the lens array 10 may be an array in which the points corresponding to the optical axes of the lenses 11 are the vertices of a square or a rectangle when the lenses 11 are viewed in a direction parallel to the optical axes, or it may be a densest array. In the case where the lenses 11 form a single-row array, the direction corresponding to the above-mentioned n may be defined as the first direction or the main-scanning direction. In the case where the lenses 11 form a two-dimensional array, the direction corresponding to the larger of the above-mentioned m and I may be defined as the first direction or the main-scanning direction. The direction perpendicular to the optical axes or central axes of the lenses 11 and perpendicular to the first direction (main-scanning direction) may be defined as the sub-scanning direction.

FIG. 2 is a perspective view schematically showing an example of the lens array 10. As shown in FIG. 2, in the lens array 10, each lens 11 is, for example, a rod lens, and the lenses 11 form a single-row array. In FIG. 2, x, y, and z indicate the directions of the x-, y-, and z-axes of a Cartesian coordinate system. The x direction is the main-scanning direction, the y direction is the sub-scanning direction, and the central axes of the lenses 11 are parallel or substantially parallel to the z direction. The following description of a lens array including a plurality of rod lenses also applies to other lens arrays, as long as there are no technical contradictions.

In a lens array, a plurality of lenses are arrayed, images formed by the respective lenses overlap, thereby a single composite image is obtained corresponding to the region where the lenses are arrayed. For example, in the case where the lens array has an erecting equal-magnification system arrangement in the relation between the object plane and the image plane, the lens array will produce an erecting equal-magnification image of the object plane or the object point.

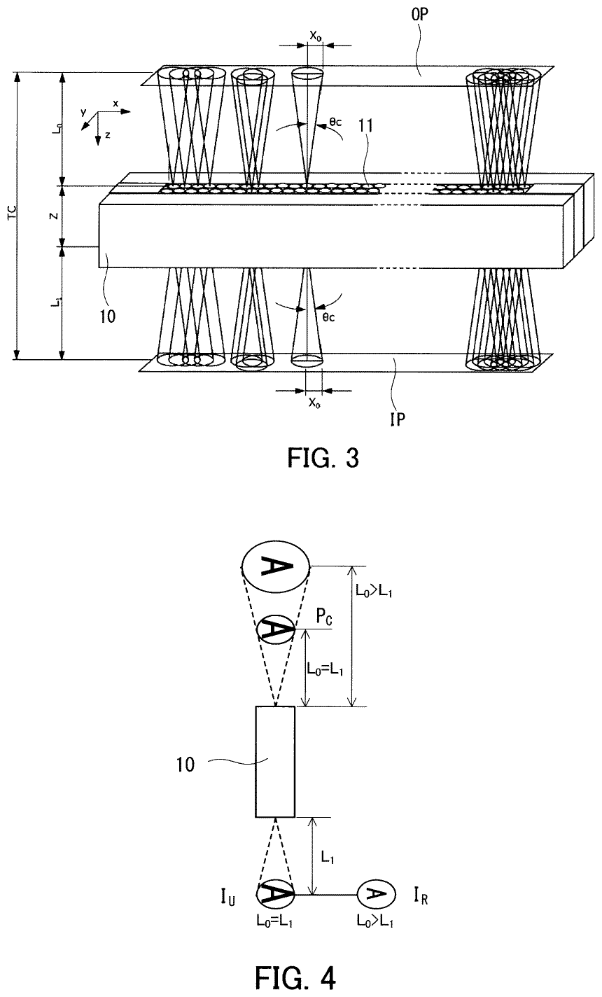

FIG. 3 is a perspective view showing another example of the lens array 10, which shows the relation of the object plane OP and the image plane IP in the les array 10. In FIG. 3, the directions indicated by x, y, and z represent the directions of the x-, y-, and z-axes of a Cartesian coordinate system. The lenses 11 in the lens array 10 shown in FIG. 3 form a double-row array with m=2. In FIG. 3, Z is the length in the direction of the central axis of the lens 11 (z direction), L₀ is a distance between the object plane OP and the lens array 10 (the distance in the optical axis direction of the lens 11 between the object plane OP and the end surface (light-incident surface) of the lens array 10 closer to the object plane OP), and L₁ is the distance between the lens array 10 and the image plane IP (the distance in the optical axis direction of the lens 11 between the image plane IP and the end surface (light-emitting surface) of the lens array 10 that is closer to the image plane IP), and TC is the conjugation length determined by the relation TC=L₀+Z+L₁. When the rod lens is cylindrical, the optical axis of the lens 11 can be the central axis or the rotational symmetry axis of the rod lens. When the medium on the object plane is the same as the medium on the image plane (for example, the air) within the area where light passes through, and when an erecting equal-magnification system is configured in a relation between the object plane and the image plane, a requirement L₀=L₁ can be satisfied. The distance between the object plane OP or the image plane IP and the lens array 10 may be adjusted such that the resolution of the image formed on the image plane IP is highest while satisfying the requirement L₀=L₁. In addition, the values or sets of values such as L₀, L₁, and TC calculated from them may be made to correspond to the regular conjugate arrangement.

If the distance between the lens array and the object plane or the image plane deviates from the regular conjugate arrangement (a regular arrangement or an erecting equal-magnification system arrangement), the images formed by each lens will be misaligned, and the images formed by adjacent lenses will not overlap well, resulting in degradation in resolution. This is one of the factors that reduces depth of field in a lens array. A value of an overlapping degree m is an indicator of how much of the images formed by single lenses are superimposed on the composite image formed by the lens array. In FIG. 3, when the radius of the field of vision at the regular conjugate position of the single lens is X₀ [mm] and the distance between the optical axes or between central axes of adjacent lenses in the lens array (array pitch) is P₀ [mm], the overlapping degree m is expressed as m=X₀/P₀. As shown in FIG. 3, the radius of the field of vision X₀ indicates the radius of the area that can be captured by a single lens on the object plane OP. A large overlapping degree m means that there are a large number of lenses contributing to formation of a composite image per unit area on the image plane IP of the lens array. Therefore, the larger the overlapping degree m, the greater the effect of the image misalignment that occurs when the distance between the object plane OP or the image plane IP and the lens array 10 deviates from the regular conjugate arrangement at an erecting equal-magnification, and the more likely it is that the composite image obtained by the lens array will be blurred and the resolution will deteriorate. Though FIG. 3 shows a case where the lenses 11 are arrayed in two rows (m=2), the same condition will be applied to the case where the lenses 11 are arrayed in a single row or the case where the lenses 11 are arrayed in more than two rows.

FIG. 4 is a diagram showing image formation by a rod lens having a refractive index distribution. For example, a light receiving element of an image sensor can be placed on the image plane IP of the rod lens 11, and an object having a plane such as a document or workpiece can be placed on the object position or the object plane. As described above, in the case where the lens array forms an erecting equal-magnification optical system, the object plane and the image plane are in a conjugate relation of an erecting equal-magnification system (regular) that satisfies a requirement L₀=L₁. In this case, as shown in FIG. 4, an equal-magnification image I_{U} is obtained. When the object or the object plane shifts from the conjugate position P_{c} that satisfies the requirement L₀=L₁, and the relation changes to L₁<L₀, a reduced image IR is formed on the image plane IP (imaging position) (erecting reduction system). This is because the field of vision of a single lens having a given aperture angle expands with an increase of L₀, and the ratio between the object and the field of vision radius changes.

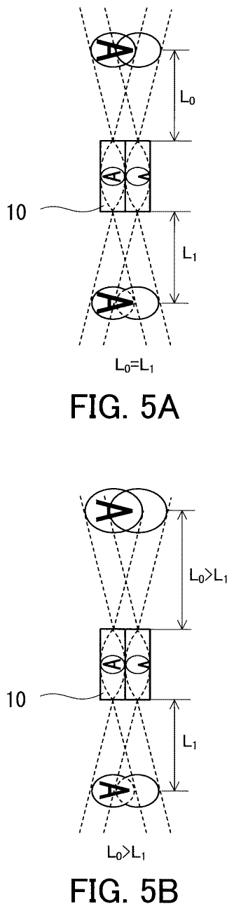

In the case where the object position in the lens array changes from the conjugate position where the requirement L₀=L₁ is satisfied, the following problems may further occur. FIG. 5A shows the image formation state of adjacent rod lenses when the object position is at the conjugate position, and FIG. 5B shows the image formation state of adjacent rod lenses when the object position is misaligned from the conjugate position. In FIG. 5A and FIG. 5B, an image of a letter “A” is formed on the image plane by two adjacent single lenses.

As shown in FIG. 5A, when the relation L₀=L₁ is satisfied, each single lens captures a part of the letter “A” in its field of vision, and an image of the same size as the object is formed on the image plane, whereby a composite image formed by two single lenses overlap without misalignment. On the other hand, as shown in FIG. 5B, when the object is misaligned from the position where the conjugate relation of L₀=L₁ is satisfied, the image formed by the two single lenses becomes a reduced image. The position and the size of the circular image formed on the image plane by the single lenses do not change because L₁ is constant. Therefore, a misalignment may occur between the object “A” and the image formed by the two adjacent single lenses, and inconsistency may occur in the composite image formed by the two single lenses. This may result in degradation of the resolution.

As mentioned above, the more the object position shifts in the direction in which L₀ increases from the conjugate position forming the erecting equal-magnification system, the magnification of the image formed by the single lens is lowered, and the resolution is lowered accordingly. This is understood to be the main factor to decrease the depth of field of the lens array. FIG. 4, FIG. 5A, and FIG. 5B are referred for explaining a case where the single lenses in the lens array are rod lenses. The same problem may occur in the case where the single lenses in the lens array are end surface-refractive lenses whose light-incident/emitting surfaces are configured with planes including curved planes. A lens array of still another optical system is configured by arraying in the main-scanning direction a lens system (cascade array) in which two or more lenses are arrayed in the optical axis direction with their optical axes aligned. In such an optical system, the lens array configures an erecting equal-magnification system in relation to the object plane and the image plane. Even in the case where such a lens array is employed, the same explanation can be applied by replacing the lens system configured by arraying lenses in the optical axis direction with the single lens explained in the present Description.

As mentioned above, when the value of the overlapping degree m in a lens array is larger, the number of lenses involved in the formation of the composite image per unit area is more likely to increase. Therefore, when the value of the overlapping degree m is greater, the decrease in resolution due to changes in the position of the object, misalignment, shifts or the like tends to be noticeable. As a result, in a lens array, the depth of field tends to decrease in proportion to the size of the parameter of the overlapping degree m.

A rod lens can be formed, for example, from a cylindrical transparent dielectric. The rod lens has, for example, a refractive index that decreases from the central axis to the periphery in the radial direction. Therefore, a beam bends inside the rod lens, and thus, for example, even if the plane on which the light enters or the plane on which the light emits is formed flat as an end surface of the rod lens, functions such as light collection can be exhibited.

In the case where the lens 11 is a rod lens, the refractive index distribution of the rod lens is approximated by Formula (1) below, for example. In addition, the numerical aperture NA of the rod lens is expressed by Formula (2). In Formula (1), r is a distance from the optical axis of the rod lens in the radial direction. n(r) is a refractive index of the rod lens at the distance r. n₀ is a refractive index at the optical axis or at the center of the rod lens. g is a refractive index distribution constant of the rod lens. r₀ is an effective radius of the rod lens. The effective radius of a rod lens is half the effective diameter, and the effective diameter, which is the amount expressed as the diameter of a circle around the central axis of the rod lens, is related to an area through which light can pass.

$${n ( r )}^{2} = {n}_{0}^{2} \{ 1 - {( g \cdot r )}^{2} \} \qquad Formula ( 1 )$$

$$N A = {n}_{0} \cdot g \cdot {r}_{0} \qquad Formula ( 2 )$$

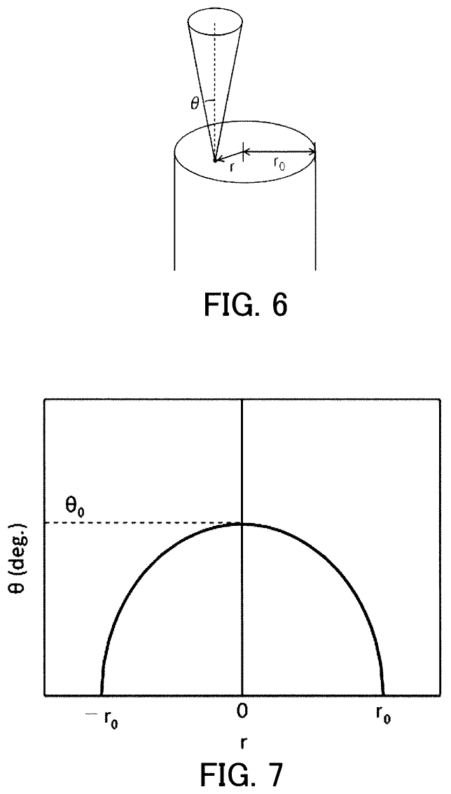

FIG. 6 schematically shows an angle θ at which light can be received at a position separated by a distance r from the center on the plane on which the light from the rod lens enters. Here, the angle at which light can be received is the angle of the beams that can contribute to image formation through the rod lens, and incident light at an angle greater than this angle is not emitted from the lens due to absorption by the side wall or the like of the rod lens. In FIG. 6, the range of light that can be received at a position separated by the distance r is represented by a cone (Acceptance Cone) with an angle θ as its apex. An angle formed by the base line of this cone and the central axis of the cone is expressed as the light receiving angle θ.

FIG. 7 is a graph schematically showing a relation between the angle θ, which is determined from the definition of the aperture of the rod lens in Formula (2), and the distance r from the central axis. As shown in FIG. 7, the light receiving angle θ at the center of the light-incident surface of the rod lens, where r=0, shows the maximum value, while the angle θ at the outer edge of the rod lens is zero. The maximum value of this angle θ is defined as the aperture angle θ₀. The maximum value of the angle θ₀ and the numerical aperture NA are related by Formula NA=sin θ₀.

The method for manufacturing the rod lens is not limited to a specific method. The rod lens can be manufactured by a method including the following (i), (ii), and (iii), for example.

(i) A glass rod having a predetermined composition and a substantially circular cross-section is obtained by a down-draw process.
(ii) A concentration gradient of an element such as Li is formed in the interior of the glass rod obtained in (i), by an ion exchange method, and a refractive index distribution is formed in the radial direction of the glass rod.
(iii) The glass rod with the refractive index distribution formed is cut in a direction substantially perpendicular to the central axis to a predetermined length and is polished so that a flat end surface is provided as a light-incident/emitting surface.

For example, the above-mentioned step (iii) includes the following (iiia) and (iiib).

(iiia) A plurality of glass rods are arrayed so that the central axes of the glass rods are substantially parallel to each other, and the glass rods are cramped with a pair of side plates.
(iiib) The glass rods are cut at an appropriate length substantially perpendicularly to the central axis of the glass rod and polished such that the rod can exhibit the desired optical performance, thereby providing a flat end surface to function as a light-incident/emitting surface. The two end surfaces corresponding to the light-incident/emitting surface arranged may be parallel.

In the optical device 1a, the transparent dielectric array 20 is arranged to overlap with the lens array 10 in a direction perpendicular to the optical axes of the lenses 11 of the lens array 10.

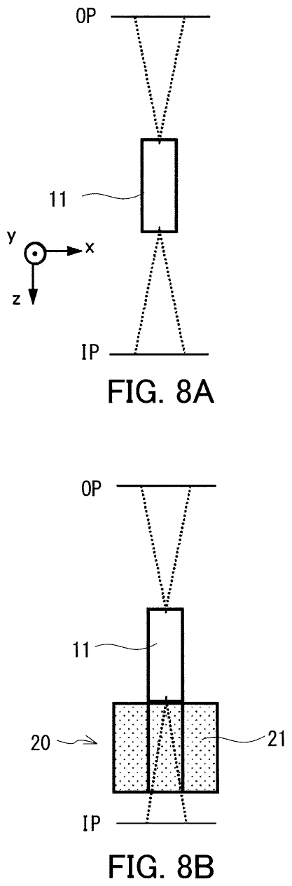

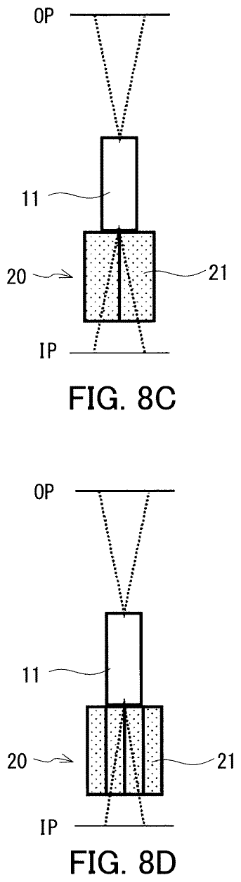

FIG. 8A is a schematic diagram showing a spread of light passing through the lens 11, which is a rod lens. FIG. 8B, FIG. 8C, and FIG. 8D each show the limitation of the field of vision when the transparent dielectric is arranged in the optical axis direction of the rod lens 11. In the optical system schematically represented in each of FIG. 8A to FIG. 8D, the medium in a space from the object plane OP to the rod lens 11 and a space from the transparent dielectric 21 to the image plane IP is the air (refractive index=1), the rod lens 11 and the transparent dielectric 21 may be in contact in the optical axis direction of the rod lens 11, or there may be a space of medium of the air between the rod lens 11 and the transparent dielectric 21 in the optical axis direction of the rod lens 11. In FIG. 8A, the directions indicated by x, y, and z represent the directions of the x-, y-, and z-axes of a Cartesian coordinate system, and the same applies to FIG. 8B to FIG. 8D. These figures represent cross-sectional views of a plane that includes the central axis of the cylindrical rod lens 11 and the central axis of the transparent dielectric 21. In these models, a system for forming an image of the object plane OP on the image plane IP is indicated, and an image of the object point on the object plane OP is formed as an erecting equal-magnification image on the image plane IP by an optical device including the rod lens 11 or an optical device including the rod lens 11 and the transparent dielectric array 20. The broken lines in the figure indicate the area in which the optical system can capture the subject on the object plane and the area in which the optical system projects the image on the image plane.

The transparent dielectric 21 in FIG. 8B to FIG. 8D has a transparent interior where light is not absorbed. Alternatively, the quantity of light absorbed within the interior of this transparent dielectric 21 is very small. This transparent dielectric 21 has a constant refractive index of 1 or more (equal to or greater than the refractive index of the air). The light that reaches the side face of the transparent dielectric 21 is absorbed partly or wholly. This makes it possible to block the light. The thickness of the part to absorb the light reaching the side face of the transparent dielectric 21 is as small as possible, and the thickness may be considered to be zero. In addition, in the case where the side face of the transparent dielectric is coated with a black coating to absorb light, its thickness may be 50 μm or less. Such transparent dielectrics 21 can be arrayed to configure a transparent dielectric array 20. In other words, the transparent dielectric array includes a plurality of transparent dielectrics having a constant refractive index and configured such that the side faces (periphery) absorb a part of the light. The transparent dielectrics are arrayed such that their central axes are approximately parallel to each other and integrated to form the transparent dielectric array.

The shape of the transparent dielectric 21 is not limited to a specific shape. The transparent dielectric 21 is, for example, columnar. The transparent dielectric 21 may be cylindrical, or it may be a polygonal column, such as a square column or a hexagonal column. The transparent dielectric 21 may be an elliptical column or an oval column. In this case, the field of vision in a specific direction is likely to be limited.

As for a transparent dielectric with a refractive index of 1, it may be a thin-walled cylindrical shape, or it may be a transparent dielectric array (or, to be precise, a cylindrical array) arrayed in at least one direction with the central axis of the cylinder parallel, if the air is understood as a dielectric.

In FIG. 8A, the distance between the object plane OP and the light-incident surface of the rod lens 11 is equal to the distance between the light-emitting surface of the rod lens 11 and the image plane IP. It should be noted that, in FIG. 8B to FIG. 8D, the distance between the object plane OP and the light-incident surface of the rod lens 11 is different from the distance between the light-emitting surface of the rod lens 11 and the image plane IP because the transparent dielectric 21 has a constant refractive index. The light-emitting surface of the rod lens 11 (the plane opposite the object plane OP) and the light-incident surface of the transparent dielectric array 20 (the plane opposite the image surface IP) may be in contact with each other or separated from each other.

In FIG. 8A, the rod lens 11 is configured to form an erecting equal-magnification image of an object point. Therefore, the aperture angle θ₀, which is the maximum value of the light receiving angle, makes the beam spread at the aperture angle θ₀ that is the maximum value of the angle θ at the center of the plane of the rod lens 11 from which the light is emitted. For this reason, the present invention will focus on the beams emitted from the center of the rod lens 11 with regard to the field of vision limitation caused by the transparent dielectric 21.

In FIG. 8A, as described above, the object plane OP, the rod lens 11, and the image plane IP are arranged in the conjugate position of the erecting equal-magnification image system. In FIG. 8A, the broken lines schematically show the spread of a beam corresponding to the aperture of the rod lens 11. In FIG. 8A, since the transparent dielectric 21 is not provided, the field of vision radius of the object plane OP and the imaging radius of the image plane position are in a relation of a conjugate position, and since there is nothing to block them, the diameters become equivalent.

In FIG. 8B, first, three transparent dielectrics 21 each having a diameter substantially equal to the diameter of the rod lens are arrayed such that their central axes are parallel to each other and the end surfaces perpendicular to the central axis of each transparent dielectric 21 are flush with each other. In this manner, a transparent dielectric array 20 is formed. The transparent dielectric 21 is arranged to be closer to the image plane IP of the rod lens 11, so that the central axis of one of the transparent dielectrics 21 is aligned with an extension of the central axis of the rod lens 11, and the light-emitting surface of the rod lens 11 (the end surface of the rod lens 11 closer to the image plane IP) and the light-incident surface of the transparent dielectric 21 (the end surface of the transparent dielectric 21 closer to the rod lens 11) face each other in parallel. The lens array 10 and the transparent dielectric array 20 satisfy the requirement expressed by the following Formula (3), for example. In Formula (3), H is a length [mm] in the direction of the central axis of the transparent dielectric 21. n₁ is the refractive index of the transparent dielectric 21, and 1≤n₁ or 1.2≤n₁≤2.0 or 1.4≤n₁≤1.8. In the case where the refractive index n₁ of the transparent dielectric is 1, the transparent dielectric may be configured to have a thin-walled cylindrical shape. In addition, by using an organic-inorganic hybrid material containing hollow particles of silica or magnesium fluoride (for example, a material including a binder such as alkoxysilane or its hydrolysate or polymer, containing hollow particles), a transparent dielectric material with a refractive index n₁ close to 1 can be formed. P₁ is a distance [mm] between the central axes of adjacent transparent dielectrics 21 in the transparent dielectric array 20 (transparent dielectric array pitch). The left-hand side is a distance between the light-emitting point of the opposing plane (light-emitting surface) of the transparent dielectric 21 when light enters at the center of the end surface (light-incident surface) of the transparent dielectric 21 at an incident angle of θ₀ and the center of the light-emitting surface (using the approximation sin θ₀≈tan θ₀). The right-hand side is the radius of the (end surface) of the transparent dielectric 21, where the adjacent transparent dielectrics 21 are arrayed without any gaps.

tan θ₀·H/n₁>P₁/2 Formula (3)

In FIG. 8B, when Formula (3) is satisfied, a part of the light emitted from the rod lens 11 reaches the side face of the transparent dielectric 21 and is absorbed, while an image is formed by the beams that do not reach the side face and pass through the transparent dielectric 21. The radius of the image formed on the image plane is smaller than the field of vision radius on the object plane OP. For example, the transparent dielectrics 21 are arrayed in the first direction (main-scanning direction) such that the distance between adjacent central axes of the transparent dielectrics 21 is equal to the diameter of the rod lens 11. Then, the spread of the light beam corresponding to the field of vision radius of each rod lens 11 is narrowed by the side faces of the transparent dielectrics 21, whereby a composite image is obtained with a substantially small overlapping degree m.

In FIG. 8C, the rod lens 11 and the transparent dielectric array 20 are the same as those explained by referring to FIG. 8B. The difference from the counterpart described by referring to FIG. 8B is that the central axis of the transparent dielectric 21 in the transparent dielectric array 20 is misaligned by half the transparent dielectric array pitch P₁ from the optical axis of the rod lens 11. When this kind of misalignment of the transparent dielectric array 20 occurs, the outermost beam through the rod lens is less likely to be blocked by the side face of the transparent dielectric 21 and is more likely to reach the image plane IP. As a result, the field of vision of the rod lens is less likely to be limited by the transparent dielectrics 21. When the rod lenses and the transparent dielectrics 21 are arrayed such that the distance between the optical axes of the rod lenses and the distance between the central axes of the transparent dielectrics 21 become equivalent in a state of a misalignment between the central axes of the transparent dielectrics 21 and the optical axes of the rod lenses, the spread of the beams corresponding to the field of vision radius of each rod lens is not narrowed by the light-blocking properties of the side faces of each transparent dielectric 21 in the transparent dielectric array 20. Therefore, the overlapping degree m in this state can be almost the same as the overlapping degree m in the state where the transparent dielectric array 20 is absent. Therefore, in the case where the diameter of the transparent dielectric 21 is equal to the diameter of the rod lens, the side face of the transparent dielectric 21 can be positioned misaligned, for example, from the optical axis of the rod lens in the array direction of the rod lens in the lens array.

In FIG. 8D, the transparent dielectric array pitch P₁ is smaller than the diameter of the rod lens 11. For example, the diameter of the transparent dielectric 21 is half the diameter of the rod lens 11, and the transparent dielectric array pitch P₁ is also adjusted to half the diameter of the rod lens. When the transparent dielectric array pitch P₁ is small like this, the aperture of the rod lens 11 is limited even if the side face of the transparent dielectric 21 is located near the straight line including the optical axis of the rod lens 11 in the array direction of the rod lens 11 in the lens array 11. In this way, the transparent dielectric array pitch P₁ in the transparent dielectric array 20 is made smaller than the distance P₀ between the optical axes of adjacent rod lenses, and a plurality of transparent dielectrics 21 are arrayed such that the transparent dielectric array 20 has a subdivided translucent portion with dimensions smaller than the diameter of the rod lens. This makes it easier to reduce the overlapping degree m, even if the transparent dielectrics 21 are arranged such that the side faces of the transparent dielectrics 21 are close to the straight line including the optical axes of the rod lenses 11 in the array direction of the rod lenses 11 in the lens array 10.

As shown in FIG. 8D, if the transparent dielectric array pitch P₁ is smaller than the diameter of the rod lens 11, there will be less necessity to precisely align the optical axis of the rod lens 11 with the central axis of the transparent dielectric 21 in order to reduce the overlapping degree m. Therefore, the depth of field is unlikely to become unstable even if there is an error in the lens array spacing of the lens 11 where the error can occur in the lens array 10. This configuration can also prevent or reduce another problem, that is, an alignment (coaxiality) between the optical axis of the rod lens 11 and the central axis of the transparent dielectric 21 will be degraded due to differences in thermal expansion that occur in each component with the temperature change.

The transparent dielectric array 20 may include, for example, a plurality of transparent dielectrics 21 arrayed in a single row or two or more rows. The transparent dielectrics 21 can function as aperture-limiting elements. In the transparent dielectric array 20, the transparent dielectrics 21 can be arranged such that the central axes of the transparent dielectrics 21 are substantially parallel to each other.

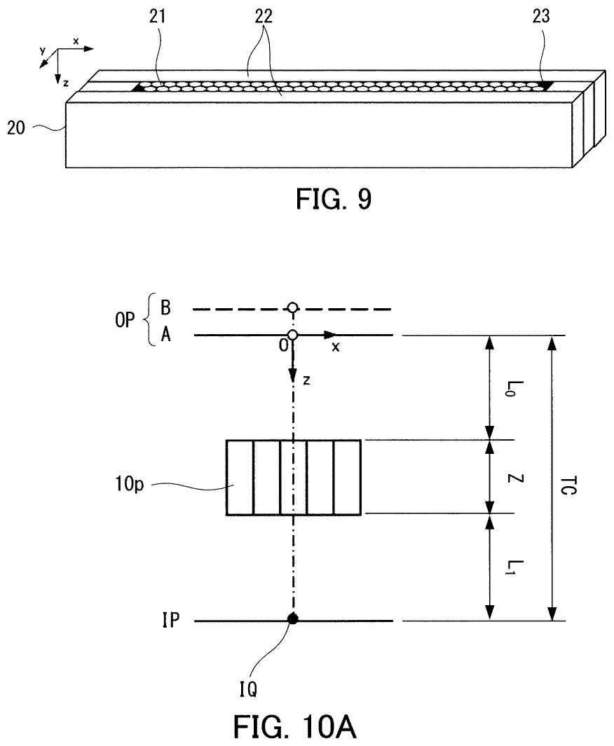

FIG. 9 is a perspective view showing an example of a transparent dielectric array 20. In FIG. 9, the transparent dielectric array 20 includes two rows of arrays, but the following explanation can also be applied to a transparent dielectric array including one row or more than two rows. The transparent dielectrics 21 are integrated by filling the gap between a pair of flat plates 22 with a resin or an adhesive 23. The flat plates 22 are, for example, fiber-reinforced plastic (FRP) plates. The resin 23 is colored black. With this configuration, it is easy to arrange, for example, a plurality of transparent dielectrics 21 in a transparent dielectric array 20 such that the transparent dielectrics 21 form a plurality of rows.

The material of the transparent dielectric 21 is not limited to a specific material.

The transparent dielectric 21 may be formed of the same type of material as the rod lens. In this case, a difference in thermal expansion is unlikely to occur between the transparent dielectrics 21 and the rod lenses, and thus, the transparent dielectric array 20 may be easily attached to the lens array 10. As for glass, although there is an increase or decrease in some metal components before and after the refractive index distribution is formed by the ion exchange method (ii) above, the glass may be regarded as being substantially the same type of material. Furthermore, the refractive index no of the central axis of the single lens that configures the rod lens array and the refractive index n₁ of the transparent dielectric may have substantially the same value. The expression “a plurality of refractive indices have substantially the same value” means that the absolute value of the difference between these refractive indices is less than 0.0005.

The transparent dielectric 21 can be formed, for example, of glass or plastic having a substantially uniform refractive index n₁. For example, the refractive index n₁ of the transparent dielectric 21 can satisfy a requirement 1≤n₁, and can satisfy a requirement 1.2≤n₁≤2.0, and can satisfy a requirement 1.4≤n₁≤1.8. The surface roughness of the side face of the transparent dielectric 21 is not limited to a specific value. The surface roughness may be adjusted such that some or all of the light that reaches the side face by passing through the interior of the transparent dielectric 21 will be scattered. For example, the arithmetic mean roughness Ra of the side face of the transparent dielectric 21 is 0.1 to 5.0 μm. The arithmetic mean roughness Ra is determined in accordance with the Japanese Industrial Standards JIS B0601:1994. A coating film may be formed on the side face of the transparent dielectric 21 to absorb a part or all of the light. This coating film may be formed with a resin colored black for example, to absorb light. The coating film may have the same effect as blackening the peripheral or the edge face of a normal lens (an optical element that include, for example, a concave surface, a convex surface, a flat surface, or a diffraction grating surface, and that refracts or diffracts light at those surfaces to diverge or to focus). As the materials used for the coating, preferably, curable resins such as an epoxy resin, an acrylic resin, a polyurethane resin, a phenolic resin, a melamine resin, an unsaturated polyester resin, an alkyd resin, a silicone resin, or a mixture of one or more thereof may be used. Furthermore, the material used for the coating preferably has a matte appearance after curing. In addition to the resins, the material to be used for the coating may also contain black particles such as carbon black, titanium black (titanium-based black pigment), magnetite-type iron (III) oxide, a copper-chromium-containing oxide, and VALIFAST BLACK (azo-chromium compound manufactured by ORIENT CHEMICAL INDUSTRIES, LTD.). Alternatively, it is possible to immerse the raw thread for the rod lens in a chloroform solution containing the VALIFAST BLACK to make the solution adhere to the side face of the raw thread, followed by evaporation of the chloroform and drying, to produce a glass rod or a raw thread for a rod lens, which has been dyed black. In addition, in the case where each lens that configures up the lens array 10 is a refractive index distribution type lens, the side faces of the transparent dielectric 21 may be coated with a resin similar to the resin used to coat the side faces of each lens with black.

The transparent dielectric array 20 may be manufactured by a method that includes for example, arraying a plurality of glass rods obtained by a down-draw process such that the central axes of the glass rods will be substantially parallel, and forming a pair of planes that are substantially perpendicular to the central axes of the glass rods to obtain the transparent dielectrics 21. The transparent dielectric array 20 may be manufactured by a method including the following (I) and (II), for example.

(I) A plurality of glass rods manufactured by a method such as a down-draw process are arrayed such that the central axes or the rotational symmetry axes of the glass rods are substantially parallel to each other, without forming a refractive index distribution inside them, and sandwiching the glass rods between a pair of plate-shaped side panels and integrate with an adhesive, a resin or the like.
(II) The glass rods each is cut to a predetermined length along a direction that is substantially perpendicular to the central axis, and polished to provide an end surface perpendicular to the central axis, thereby forming the light incident/emitting surface.

In this manner, it is also possible to make the composition of the glass that configures the transparent dielectric 21 of the manufactured transparent dielectric array 20 substantially the same as the glass composition of the glass rod obtained in (i) above. As a result, the difference in values of physical properties such as a thermal expansion coefficient and a light transmittance between the transparent dielectric 21 and the rod lens is likely to be small. Since the difference in thermal expansion coefficient between a plurality of parts is small, the relative positional relationship between the parts is unlikely to change due to expansion and contraction of the parts even when the temperature changes. As a result, the fluctuation of the optical performance is suppressed. Here, the optical performance is exhibited by the positional accuracy of the parts relative to each other and by the cooperation of the parts.

For example, a transparent dielectric 21 with the desired dimensions may be produced by stretching, while heating, a rod of glass or resin that has been pre-formed into a polygonal column or any predetermined shape.

For example, the gaps between transparent dielectrics 21 may be filled with a resin, and the resin may be cured to integrate the transparent dielectrics 21. In this case, the resin may be colored black to enhance light absorption. The resin filling may be carried out, for example, by supplying a liquid resin to one end of each void and performing vacuum suction at the other end of the voids, thereby distributing the resin throughout the gaps in the array of the transparent dielectrics 21. Alternatively, an adhesive resin colored black may be applied to the surfaces of a pair of flat plates in advance, and after arraying a plurality of transparent dielectrics 21 between the pair of the flat plates and clamping, the pair of flat plates and the transparent dielectrics 21 may be heat-pressed, whereby the voids between the transparent dielectrics 21 may be filled with the resin.

The transparent dielectric 21 may have a structure that includes a core and a cladding. In this case, the cladding may be a colored layer that absorbs a part of the light traveling towards the outer circumference or reaching near the side face of the transparent dielectric 21. The side face of the transparent dielectric 21 may preferably have a fine uneven portion for promoting scattering and absorption of light.

The array pattern of the transparent dielectrics 21 in the transparent dielectric array 20 is not limited to a specific pattern. The array pattern of the transparent dielectrics 21 may be a one-dimensional array or a two-dimensional array. In the two-dimensional array, the transparent dielectrics 21 form, for example, a plurality of rows.

In this case, the central axes of the transparent dielectrics 21 in each row can be substantially parallel.

In the optical device 1a, the requirements to be satisfied by the distance P₀ and the transparent dielectric array pitch P₁ are not limited to specific requirements. The optical device 1a preferably satisfies a requirement P₁≤0.8×P₀. This makes it easy to obtain a large depth of field with the optical device 1a, and in an apparatus equipped with the optical device 1a, it is possible to obtain an image with a high resolution and little degradation even for a subject with unevenness or height difference. The optical device 1a satisfies also a requirement 0.3×P₀≤P₁. P₀ is the distance between the optical axes of adjacent rod lenses 11 in the lens array 10, and may also be defined as the array pitch or lens-to-lens pitch of the rod lenses. P₁ is the distance between the central axes of adjacent transparent dielectrics 21 in the transparent dielectric array 20, and may also be defined as the array pitch or dielectric-to-dielectric pitch of the transparent dielectrics. By making the array pitch P₁ of the transparent dielectric material 0.3×P₀ or more, it becomes easier to prevent a reduction in light intensity, which is caused by the difficulty in covering the effective radius of the lens, and the aperture of the lens is less likely to be divided. This makes it easier to prevent the NA in the sub-scanning direction (y direction) from becoming smaller and the spot diameter from becoming larger, and in the scanning direction (x direction), this makes it easier to prevent side peaks from occurring due to the periodic structure of the transparent dielectric array. Here, P₀ and P₁ may satisfy a requirement 0.4×P₀≤P₁, or a requirement 0.5×P₀≤P₁. Further, for a single row of lens arrays, a requirement 0.45×P₀≤P₁≤0.65×P₀ may be satisfied, and a requirement 0.5×P₀≤P₁≤0.6×P₀ may be satisfied.

In the optical device 1a, the requirements satisfied by the length H [mm] in the central axis direction of the transparent dielectric 21, the refractive index n₁ of the transparent dielectric 21, the distance L₀₁ [mm] between the rod lens and the object plane, the transparent dielectric array pitch P₁, and the rod lens array pitch P₀, are not limited to specific requirements. The distance L₀₁ between the rod lens and the object plane is the distance between the object plane and the end surface of the lens closer to the object plane when the erecting equal-magnification image of an object point on the object plane is formed with the highest resolution on the image plane in an optical system including the optical device 1a. In the optical device 1a, it is preferable that a requirement H/(n₁·L₀₁)>0.27×(P₁/P₀)+0.023 is satisfied. This makes it easier for the optical device 1a to have a large depth of field, and for example, it is easier to acquire an image with a high resolution and little degradation in the optical performance, even for a subject or a workpiece that has thickness, unevenness, and height differences.

In the optical device 1a, it is desirable that the requirement H/(n₁·L₀₁)≤0.6 is satisfied. In this case, illumination unevenness is unlikely to occur in the optical device 1a.

When using an optical device in which a lens array and a transparent dielectric array are arranged so that the optical axes of the lenses of the lens array and the central axes of the transparent dielectrics are substantially parallel, the accuracy required for the array of the lenses and the transparent dielectrics is an important issue in ensuring the performance of the optical device. Hereinafter, the effect on the performance of an optical device will be considered. This is the effect of misalignment in the relative positions in the x direction and the y direction of the lenses of the lens array and the transparent dielectrics of the transparent dielectric array from their ideal positions.

For the purpose of ray tracing or image evaluation, a suitable optical system model was considered, and the effect on the depth of field at the time the relative positions of the rod lens array and the transparent dielectric array were changed was examined using the geometrical optics calculation software OSLO Premium rev 6 by Lambda Research Corporation in the United States.

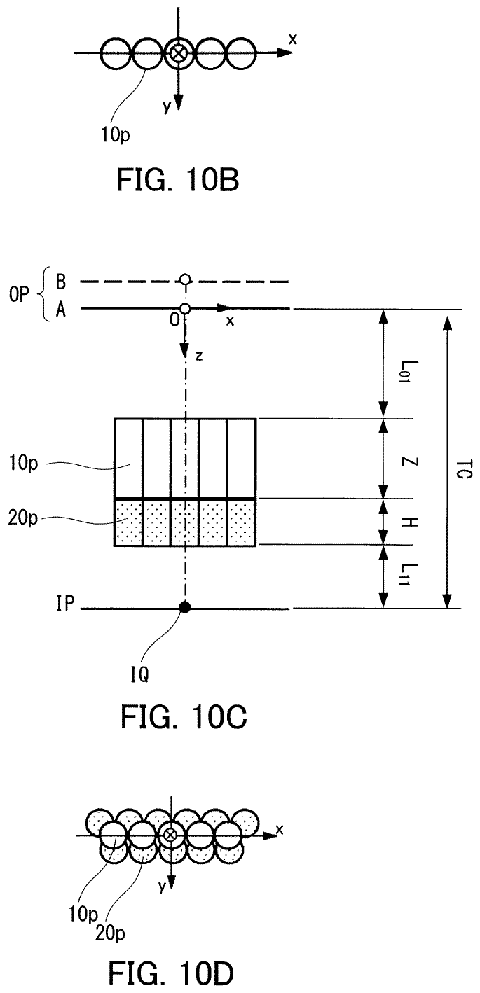

FIG. 10A is a schematic diagram showing an optical system including the object plane OP, the rod lens array 10p, and the image plane IP. The object plane OP is assumed to be a plane perpendicular to the paper plane, and a point on the object plane OP at the position indicated by A is taken as the origin. An axis passing through the origin and perpendicular to the object plane OP and directed to the image plane IP was taken as a z-axis; an axis passing through the origin, perpendicular to the z-axis and parallel to the paper plane, was taken as an x-axis; and an axis passing through the origin, perpendicular to the x-axis, z-axis, and the paper plane, was taken as a y-axis. The rod lenses 10p were arrayed in a single row in the x direction, with the central axis of one of the rod lenses in the rod lens array 10p arranged to substantially be aligned with a part of the z-axis. In the case of a cylindrical rod lens or a rotationally symmetric lens, the central axis or the rotational symmetry axis can also be regarded as the optical axis of the lens. Therefore, it is also possible to say that the z-axis is defined to be substantially aligned with the optical axis of the rod lens. The erecting equal-magnification image IQ of the object point on the object plane OP at the position indicated by A in FIG. 10A is formed with the highest resolution on the image plane IP by the rod lens array 10p. It is assumed that the object plane OP indicated by A, the rod lens array 10p, and the image plane IP are in the regular arrangement.

FIG. 10B is a schematic diagram showing the optical system shown in FIG. 10A viewed from the object plane OP in the z direction. The object plane OP, the rod lens array 10p, and the image plane IP are assumed to be placed in the air (refractive index=1).

FIG. 10C is a schematic diagram showing the optical system including the object plane OP, the rod lens array 10p, the transparent dielectric array 20p, and the image plane IP. The object plane OP is assumed to be a plane perpendicular to the paper plane, and the point on the object plane OP indicated by A in FIG. 10C is taken as the origin. An axis passing through the origin and perpendicular to the object plane OP and directed to the image plane IP was taken as a z-axis; an axis passing through the origin, perpendicular to the z-axis and parallel to the paper plane, was taken as an x-axis; and an axis passing through the origin, perpendicular to the x-axis, z-axis and paper plane, was taken as a y-axis. The rod lenses 10p were arrayed in a single row in the x direction, with the central axis of one of the rod lenses in the rod lens array 10p arranged to be substantially aligned with a part of the z-axis. In the case of a cylindrical rod lens or a rotationally symmetric lens, the central axis or the rotational symmetry axis can also be regarded as the optical axis of the lens. Therefore, it is also possible to say that that the z-axis is defined to be substantially aligned with the optical axis of the rod lens. The erecting equal-magnification image IQ of the object point on the object plane OP at the position indicated by A in FIG. 10C is formed with the highest resolution on the image plane IP by the optical system including the rod lens array 10p and the transparent dielectric array 20p. The object plane OP at the position indicated by A, the optical device including the rod lens array 10p and transparent dielectric array 20p, and the image plane IP are in the regular arrangement.

FIG. 10D is a schematic diagram showing the optical system shown in FIG. 10C viewed in the z direction from the object plane OP. The object plane OP, the rod lens array 10p, the transparent dielectric array 20p, and the image plane IP are assumed to be placed in the air (refractive index=1). As shown in FIG. 10D, the transparent dielectric array 20p was configured by overlapping in the y direction the transparent dielectric arrays arrayed in a single row in the x direction, so that the gaps would be minimized (double-row array). The transparent dielectric array 20p was arranged such that the x−z plane bisected the width of the transparent dielectric array 20p in the y direction and the y−z plane included the central axis of one of the transparent dielectrics in the transparent dielectric array 20p and the central axis of the rod lens.

As mentioned above, the object point at the origin on the object plane OP represented by A and the image point IQ are at a conjugate positional relation of the erecting equal-magnification system. In the case where the object plane OP is at the position A, the intersection point of the extension line of the optical axis of a specific rod lens and the object plane OP is also the origin of the coordinate system specified by the x-axis, y-axis, and z-axis. A point light source was placed at this origin, and the image formed by this light source at the image plane IP was evaluated. The light source was assumed to be an ideal point light source.

In the optical systems shown in FIG. 10A to FIG. 10D, the rod lens array 10p was assumed to have the optical performance shown in Table 1. In the Table, L₀ represents a distance between the rod lens array 10p and the object plane OP in the optical system including the rod lens array 10p shown in FIG. 10A and FIG. 10B, where the erecting equal-magnification image of the object plane OP at the position indicated by A is formed on the image plane IP with the highest resolution, that is, in the regular arrangement.

TABLE 1

| | | | Specification |
|---|---|---|---|
| Item | Symbol | Unit | value |
| Number of rows of rod | | | 1 |
| lens array | | | |
| Central refractive Index | n₀ | | 1.600 |
| Refractive index | g | [/mm] | 0.4400 |
| distribution constant | | | |
| Lens period length | PP = 2π/g | [mm] | 14.28 |
| Lens array pitch | P₀ | [mm] | 0.600 |
| Rod lens diameter | D₀ | [mm] | 0.600 |
| Rod lens effective radius | r₀ | [mm] | 0.285 |
| Numerical aperture | NA ≈ | | 0.20 |
| | n₀ · g · r₀ | | |
| Aperture angle | θ₀ | [deg.] | 11.5 |
| Lens Length | Z | [mm] | 7.65 |
| Lens conjugation length | TC | [mm] | 33.01 |
| Distance between lens | L₀ | [mm] | 12.68 |
| and object plane | | | |
| Ratio of distance between | L₀/PP | | 0.89 |
| lens and object | | | |
| plane to lens period length | | | |

The transparent dielectrics that configure the transparent dielectric array 20p included in the optical device shown in FIG. 10C or FIG. 10D is a transparent dielectric cylinder made of a medium having a uniform refractive index n₁, exhibiting no absorption. Here, it was assumed that no scattering occurs at the end surface of the transparent dielectric where light enters and exits, and that Snell's law is strictly followed. It was assumed further that a light-absorbing layer having a negligible thickness and capable of absorbing light reaching there is formed on the side face of the transparent dielectric material.

In the optical system shown in FIG. 10C and FIG. 10D, the rod lens array 10p was the same rod lens array used in the optical system shown in FIG. 10A and FIG. 10B, as described in Table 1. The transparent dielectric array 20p was prepared to have the properties and physical quantities shown in Table 2. FIG. 10C and FIG. 10D show an optical system including an optical device including the rod lens array 10p and the transparent dielectric array 20p. In the optical system, when an erecting equal-magnification image of the object plane OP was formed on the image plane IP with the highest resolution, i.e., when the rod lens array 10p was in the regular arrangement, the distance between the object plane OP and the end surface of the rod lens array 10p on the object plane OP was acquired as L₀₁. From the relation shown in FIG. 10C and FIG. 10D, it can be considered that a rod lens array 10p was inserted into the optical system including the rod lens array 10p shown in FIG. 10A and FIG. 10B, and a transparent dielectric array was inserted immediately thereafter. Therefore, the distance L₀₁ in the regular arrangement shown in FIG. 10C and FIG. 10D is approximately the same value as the distance L₀ in the regular arrangement shown in FIG. 10A and FIG. 10B. The fact that the two numerical values for the distance between the end surface of the rod lens array and the object plane are substantially the same means that the absolute value of the difference between the two values is less than 2% of the reference value. In Table 2, the values of P₁/P₀ and H/(n₁·L₀₁) or the like of the transparent dielectric array 20p represented by (i) to (v) also include the relation with the rod lens array 10p represented by Table 1 included in each optical device combined with them at the regular position.

TABLE 2

| | | | Transparent dielectric array | | | | |
|---|---|---|---|---|---|---|---|
| Specification | Symbol | Unit | (i) | (ii) | (iii) | (iv) | (v) |
| Number of rows of | | | 2 | 2 | 2 | 2 | 2 |
| transparent dielectric array | | | | | | | |
| Refractive index of | n₁ | | 1.600 | 1.600 | 1.600 | 1.600 | 1.600 |
| transparent dielectric | | | | | | | |
| Array pitch of transparent | P₁ | mm | 0.600 | 0.540 | 0.480 | 0.360 | 0.240 |
| dielectric | | | | | | | |
| Diameter of transparent | D₁ | mm | 0.600 | 0.540 | 0.480 | 0.360 | 0.240 |
| dielectric | | | | | | | |
| Effective radius of | r₁ | mm | 0.285 | 0.257 | 0.228 | 0.171 | 0.114 |
| transparent dielectric | | | | | | | |
| Ratio of array pitch of | P₁/P₀ | | 1.0 | 0.9 | 0.8 | 0.6 | 0.4 |
| transparent dielectric to | | | | | | | |
| array pitch of rod lens array | | | | | | | |
| Length of transparent | H | mm | 9.60 | 8.64 | 7.68 | 5.76 | 3.84 |
| dielectric | | | | | | | |
| Ratio of length of transparent | H/(n₁ · L₀₁) | | 0.473 | 0.426 | 0.379 | 0.284 | 0.189 |
| dielectric array to L₀₁, divided | | | | | | | |
| by refractive index | | | | | | | |

In the optical simulation, in the case of performing optical calculations for the optical system including the rod lens array 10p shown in FIG. 10A and FIG. 10B, a point light source was placed at the origin on the object plane at the position indicated by A in the figures. The point light source was placed at the origin O, so that light of a wavelength 570 nm is emitted with no intensity difference depending on the angle, and calculations were performed to trace 7,380 beams. The same applies to the following optical calculations where the point light source is used. In the process of adjusting the distance between the object plane OP and the image plane IP, L₀ and L₁, both of which are expressed by Formula (4) of the erecting equal-magnification image system of the rod lens array, were obtained to arrange the object plane OP, the rod lens array, and the image plane IP.

$${L}_{0} = {L}_{1} = - ( 1 / {n}_{0} ) \cdot tan ( π \cdot Z / PP ) \qquad Formula ( 4 )$$

In this way, regular arrangements for both L₀ and L₁ were obtained, and the conjugate point on the image plane IP, being the origin on the object plane OP at this time was determined as the image point IQ. Adjustment of the resolution on the calculated image plane in the simulation and the setting of the requirements for obtaining the highest resolution were carried out as follows. First, the rod lens array 10p represented by the parameters in Table 1 was provided along with the object plane OP and the image plane IP, together with L₀ and L₁ calculated by Formula (4), and then, a spot diagram of the image on the image plane IP was obtained. A lateral ray aberration as the distance from the image point IQ for each ray on the image plane IP was then calculated. Then, the root mean square (rms) value of the ray aberration was calculated to obtain rms_{A} as the evaluation index of the image, and the higher-order coefficients of the rod lens array 10p were optimized such that the rms_{A} value would be minimized. This is equivalent to correcting the spherical aberration on the axis. The higher-order coefficients of the rod lens array 10p are coefficients h₄ and h₆ when the refractive index distribution n(r) of the rod lens is expressed by the following Formula (5).

$${n}^{2} ( r ) = {n}_{0}^{2} \cdot \{ 1 - {( g \cdot r )}^{2} + {{h}_{4} ( g \cdot r )}^{4} + {{h}_{6} ( g \cdot r )}^{6} \} \qquad Formula ( 5 )$$

Next, the object plane OP at the position indicated by B in the figure creates an object plane at the time the object plane OP at the position indicated by A in the figure is shifted by −1 [mm] in the z direction together with the point light source. At this time, the distance between the rod lens and the object plane is L₀+1 [mm]. In the case of an arrangement of an optical system with an object plane OP shifted in this way, the spot diagram of the image on the image plane IP was acquired in the same way, and the lateral ray aberration, which is the distance from the image point IQ for each beam at the image plane IP, was calculated, and the root mean square (rms) value of the ray aberration was calculated as the evaluation index of the image as rms_{B}. The position B corresponds to a so-called “floating” state in which a document or a workpiece, which should be at the position A, is displaced in the direction away from the rod lens array or the image sensor including the rod lens array. In an optical system that includes an object plane OP at the position indicated by B that is shifted from the position indicated by A related to the regular arrangement, a so-called defocusing shift of the image plane IP, which may be performed to reduce the increased rms value (to improve image formation performance and light-collecting properties), is not performed.

In the simulation under the aforementioned conditions, the rms_{A} value at the position A was 0.0041 [mm], while the rms_{B} value at the position B was 0.1014 [mm]. In the case where the object plane OP shifted from the position A as a regular arrangement to the position B, the rms value of the ray aberration increased, resulting in a degradation in the image formation performance. Here, any compensation or defocusing (position adjustment of the image plane IP) for the purpose of improving the rms value of the image on the image plane IP in conjunction with the shift to the position B was not performed. The ratio rmsᵣ of rms_{A} at the position A to rms_{B} at the position B was 0.040. It can be understood that in an optical system including a rod lens array, the image formation performance will deteriorate to this extent in the case where there is “floating” (shift in the −z direction) of the workpiece or the document.

In evaluating an image of the optical system shown in FIG. 10C and FIG. 10D, the regular position of the optical system including the rod lens array 10p shown in Table 1 was first determined, and the rms_{B} on the image plane IP with respect to the object plane OP shifted by −1 [mm] in the z direction was determined in the same way as the calculation method explained based on the aforementioned FIG. 10A and FIG. 10B. The actually calculated value was the same, namely, rms_{B}=0.1014 [mm]. Next, an optical system was configured by arranging the rod lens array 10p with each of the transparent dielectric arrays 20p shown in Table 2, and a regular arrangement of the object plane OP at the position indicated by A, the optical system including the rod lens array 10p and the transparent dielectric array 20p, and the image plane IP, were determined. At that time, the distance L₀₁ between the object plane OP and the end surface of the rod lens array 10p closer to the object plane OP was substantially the same as L₀. The object plane OP at the position indicated by B in the figure is the object plane OP at the position indicated by A in the figure, shifted by −1 [mm] in the z direction together with the point light source. At that time, the distance between the rod lens and the object plane is Loi+1 [mm]. The following calculations and evaluations are not limited to the case of an optical system in which the object plane OP is shifted in the −z direction, the point light source is shifted in the direction parallel to the x-axis (x direction) by 0, 0.25, 0.50, and 0.75 times the diameter of each transparent dielectric shifts of 0 mm, 0.25×D₁ mm, 0.5×D₁ mm, and 0.75×D₁ mm (D₁ is the diameter of the transparent dielectric), and 0 mm, 0.1 mm, and 0.2 mm shifts in the direction parallel to the y-axis (y direction). For each of the transparent dielectric arrays 20p in (i) to (v), twelve point light sources were shifted in the x-axis direction and the y-axis direction to obtain the spot diagram of each image on the image plane IP. The number of the spot diagrams obtained was as many as 5×12=60. For the spot diagram obtained, the lateral ray aberration, which is the distance from the image point IQ for each beam on the image plane IP, was calculated, and the root mean square (rms) value of the ray aberration was calculated as an evaluation index of the image as rms^{(k)}_{(m×p)} at the position B. For the rms^{(k)}_{(m×p)}, k is 0.4, 0.6, 0.8, 0.9, and 1.0, which is the subscript corresponding to P₁/P₀ of the transparent dielectric arrays (i) to (v) shown in Table 2; m is 0, 0.25, 0.50, and 0.75, which is a subscript specifying the coefficient of the shift in the x direction; and p is 0, 0.1, and 0.2, and is a subscript specifying the amount of shift in the y direction. Finally, the ratio rmsᵣ^{(k)}_{(m×p)} of rms^{(k)}_{(m×p)} to rms_{B} was calculated (the subscript attributes of k, m, and p are the same). In the calculation, the followings are taken into consideration: a state in which the document being moved from the height where it should be in a direction away from the optical system or the image sensor including the optical system (−z direction), that is, a so-called “floating” state; and furthermore, a state in which the object point on the document is misaligned in a plane perpendicular to the z-direction. In an examination of an optical system that includes the position B where the object plane is shifted from the regular position A, the defocusing shift of the image plane IP is not performed in the same way.

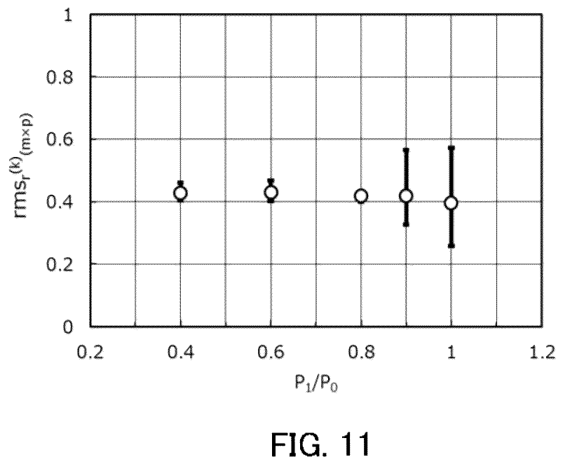

FIG. 11 is a graph showing a relation between the ratio rmsᵣ^{(k)}_{(m×p)} of rms of the ray aberration and P₁/P₀ in an optical system including a rod lens array 10p and a transparent dielectric array 20p. In FIG. 11, the values represented by the white circles plotted for each P₁/P₀ are the average values of the rmsᵣ^{(k)}_{(m×p)} calculated using the twelve shift patterns for one P₁/P₀. The error bar for each P₁/P₀ indicates the maximum and minimum values of the ratio rmsᵣ^{(k)}_{(m×p)} for the twelve shift patterns at the same P₁/P₀. The size of the error bar indicates the range of rmsᵣ^{(k)}_{(m×p)} at each P₁/P₀. The ratio rmsᵣ^{(k)}_{(m×p)} for the optical system shown in FIG. 10C and FIG. 10D was within the range of 0.4 to 0.45 on average at each P₁/P₀. This value is about 10 times larger than the value of rmsᵣ (0.040) for the optical system including a rod lens array 10p while not including a transparent dielectric array 20p. Therefore, it can be understood as follows: even if there is a shift in the x direction and the y direction in addition to the shift in the −z direction from the object plane OP indicated by the position A, which is related to the regular arrangement, there is little degradation of optical performance in the optical system that includes the rod lens array 10p and the transparent dielectric array 20p.

Looking more closely at the maximum value of the error bar, the maximum value of the ratio rmsᵣ^{(k)}_{(m×p)} (k=0.9 to 1.0) for the case where P₁/P₀ is 0.9 and 1 is greater than the maximum value of the ratio rmsᵣᵣ^{(k)}_{(m×p)} (k=0.4 to 0.8) for the case where P₁/P₀ is 0.8 or less. It is therefore understood that an optical system including a transparent dielectric array generally has the effect of increasing the depth of field. However, in an optical system having an arrangement of a rod lens array and a transparent dielectric array, where the array of P₁/P₀ is 0.9 or more, the reduction in the resolution due to shifts in the x direction and the y direction cannot be sufficiently compensated for. As a result, the depth of field may be reduced. Therefore, even in the case where a shift occurs in the x direction and in the y direction, in order to achieve a large depth of field, the array pitch P₁ of the transparent dielectrics in the transparent dielectric array is desirably 0.8 times or less the array pitch P₀ of the rod lens array (P₁/P₀≤0.8). Preferably, the array pitch P₁ of the transparent dielectric array is at least 0.3 times the array pitch P₀ of the rod lens array (0.3 s P₁/P₀). In the case where P₁ is at least 0.3×P₀, it will be easy to prevent light reduction and splitting of the lens aperture. This makes it possible to prevent the NA in the sub-scanning direction (y direction) from becoming smaller and the spot diameter from becoming larger, and also to prevent side peaks from occurring in the scanning direction (x direction) due to the periodic structure of the transparent dielectric array.

Further evaluation was carried out on an optical device including the rod lens array 10p and the transparent dielectric array 20p. Instead of the rod lens array 10p having the optical performance shown in Table 1, a rod lens array α, β, or γ having the optical performance shown in Table 3 was used, and a transparent dielectric array including a group a, a group b, or a group c having the performance and the specifications shown in Table 4 to Table 12 was used. Table 4 shows specifications and requirements for an optical device including a set of a rod lens array a and a transparent dielectric array group a; Table 5 shows specifications and requirements for an optical device including a set of the rod lens array a and a transparent dielectric array group b; Table 6 shows specifications and requirements for an optical device including a set of the rod lens array a and a transparent dielectric array group c; Table 7 shows specifications and requirements for an optical device including a set of a rod lens array β and the transparent dielectric array group a; Table 8 shows specifications and requirements for an optical device including a set of the rod lens array β and the transparent dielectric array group b; Table 9 shows specifications and requirements for an optical device including a set of the rod lens array β and the transparent dielectric array group c; Table 10 shows specifications and requirements for an optical device including a set of a rod lens array γ and the transparent dielectric array group a; Table 11 shows specifications and requirements for an optical device including a set of the rod lens array γ and the transparent dielectric array group b; and Table 12 shows specifications and requirements for an optical device including a set of the rod lens array γ and the transparent dielectric array group c.

First, for each the rod lens arrays α, β, and γ shown in Table 3, a regular arrangement, a distance L₀ between the rod lens array and the object plane OP in the regular arrangement, a spot diagram on the image plane IP when the object plane OP and the point light source are shifted by 1 [mm] in the −z direction, and a value ^{(h)}rms_{B} calculated from the spot diagram, were calculated in a manner similar to the method explained with reference to FIG. 10A, FIG. 10B and figures thereof. In the value (h)rms_{B}, h is α, β, or γ, which is the subscript specifying the rod lens array shown in Table 3. The regular arrangement is an arrangement in which the distance between the object plane OP and the rod lens array and the distance between the rod lens array and the image plane IP are adjusted such that the erecting equal-magnification image of the object point on the object plane OP is formed with the highest resolution on the image plane IP.

Next, Table 4 refers to an optical device including a set of a rod lens array a and a transparent dielectric array group a. In the transparent dielectric array group a, P₁/P₀=0.4, and six types of transparent dielectric arrays with H within the range of 1.920 to 38.400 mm were prepared. A rod lens array a and one of the transparent dielectric arrays (H=0.192 mm, H/(n₁·L₀₁)=0.032) in the transparent dielectric array group a were arranged to form an optical device including a rod lens array and a transparent dielectric array.

A regular arrangement, a distance^{(h)}L₀₁^{(k)}₍ₛ₎ between the rod lens array and the object plane OP in the regular arrangement, a spot diagram on the image plane IP where the object plane OP and the point light source being shifted by 1 [mm] in the −z direction, and a value ^{(h)}rms_{B}^{(k)}₍ₛ₎ calculated from the spot diagram, were calculated in a manner similar to the method explained with reference to FIG. 10C, FIG. 10D and figures thereof. Then, the ratio^{(h)}rmsᵣ^{(k)}₍ₛ₎ of ^{(h)}rms_{B}^{(k)}₍ₛ₎ to (h)rms_{B} was calculated. As for ^{(h)}L₀₁^{(k)}₍ₛ₎, ^{(h)}rms_{B}^{(k)}₍ₛ₎, and ^{(h)}rmsᵣ^{(k)}₍ₛ₎, the meanings of the respective subscripts are as follows: h is α, β, or γ, and is a subscript specifying the rod lens array shown in Table 3, which is a in Table 4; k is 0.4, 0.6, or 0.8, and is a subscript specifying P₁/P₀, which is 0.4 in Table 4; and, s is a numerical value within the range of 0.032 to 0.637, and is a subscript specifying H/(n₁·L₀₁), which is 0.032 here.

In the same way, with reference to Table 4, optical devices were configured each to include a rod lens array a and another transparent dielectric array belonging to the transparent dielectric array group a, and a value ^{(h)}rmsᵣ^{(k)}₍ₛ₎ for each optical device was calculated. Here, h is a; k is 0.4; and s is a number within the range of 0.064 to 0.637, and is a subscript specifying H/(n₁·L₀₁).

Furthermore, with reference to Table 5, optical devices were configured each to include a rod lens array a and a transparent dielectric array belonging to the transparent dielectric array group b, and a value ^{(h)}rmsᵣ^{(k)}₍ₛ₎ for each optical device was calculated. Here, h is a; k is 0.6; and s is a numerical value within the range of 0.095 to 0.764, and is a subscript specifying 6 levels of H/(n₁·L₀₁)).

Furthermore, with reference to Table 6, optical devices were configured each to include a rod lens array a and a transparent dielectric array belonging to the transparent dielectric array group c, and a value ^{(h)}rmsᵣ^{(k)}₍ₛ₎ for each of the optical devices was calculated. Here, h is α, k is 0.8; and s is a numerical value within the range of 0.127 to 0.764, and is a subscript specifying the 5 levels of H/(n₁·L₀₁).

Based on the above description, an rms index that represents the image formation state with a shift in the −z direction being applied to the object plane was calculated. This index relates to an optical device including the rod lens array α and a transparent dielectric array belonging to the transparent dielectric array groups a to c.

Similarly, with reference to Table 7 to Table 9, an rms index (h)rmsᵣ^{(k)}₍ₛ₎ that represents the image formation state where a shift in the −z direction being applied to the object plane was calculated. This index relates to an optical device including a set of a rod lens array β and a transparent dielectric array belonging to the transparent dielectric array groups a to c. Here, h is α, β, or γ, which is a subscript specifying the rod lens array shown in Table 3, and here it is μ; k is 0.4, 0.6, and 0.8, which is a subscript specifying P₁/P₀; and s is a subscript specifying H/(n₁·L₀₁).

Similarly, with reference to Table 10 to Table 12, an rms index (h)rmsᵣ^{(k)}₍ₛ₎ that represents the image formation state where a shift in the −z direction being applied to the object plane was calculated. This index relates to an optical device including a set of a rod lens array γ and the transparent dielectric array belonging to the transparent dielectric array groups a to c. Here, h is α, β, or γ, which is the subscript specifying the rod lens array shown in Table 3, and here it is γ; k is 0.4, 0.6, or 0.8, which is the subscript specifying P₁/P₀; and s is a subscript specifying H/(n₁·L₀₁).

TABLE 3

| | | | Rod lens array | | |
|---|---|---|---|---|---|
| Item | Symbol | Unit | α | β | γ |
| Number of rows | | | 1 | 1 | 1 |
| Central refractive | n₀ | | 1.600 | 1.600 | 1.600 |
| index | | | | | |
| Refractive index | g | /mm | 0.1667 | 0.4000 | 0.8333 |
| distribution constant | | | | | |
| Lens period length | PP = 2π/g | mm | 37.70 | 15.71 | 7.54 |
| Lens array pitch | P₀ | mm | 0.600 | 0.600 | 0.600 |
| Rod lens diameter | D₀ | mm | 0.600 | 0.600 | 0.600 |
| Rod lens effective | r₀ | mm | 0.285 | 0.285 | 0.285 |
| radius | | | | | |
| Numerical aperture | NA ≈ | | 0.0760 | 0.1824 | 0.3800 |
| | n₀ · g · r₀ | | | | |
| Aperture angle | θ₀ | | 4.4 | 10.5 | 21.8 |
| Lens Length | Z | mm | 20.039 | 8.350 | 4.008 |
| Lens conjugation | TC | mm | 95.4 | 39.8 | 19.1 |
| length | | | | | |
| Distance between rod | L₀ | mm | 37.7 | 15.7 | 7.5 |
| lens array and object | | | | | |
| plane | | | | | |

TABLE 4

| Item | Symbol | Unit | α-a-1 | α-a-2 | α-a-3 | α-a-4 | α-a-5 | α-a-6 |
|---|---|---|---|---|---|---|---|---|
| Rod lens array to be | | | Rod lens array α | | | | | |
| arranged | | | | | | | | |
| Array pitch of | P₁ | mm | 0.4 × P₀ | | | | | |
| transparent dielectric | | | | | | | | |
| Number of rows of | m | | 2 | | | | | |
| transparent dielectric | | | | | | | | |
| array | | | | | | | | |
| Refractive index of | n₁ | mm | 1.600 | | | | | |
| transparent dielectric | | | | | | | | |
| Diameter of | D₁ | mm | 0.240 | | | | | |
| transparent dielectric | | | | | | | | |
| Effective radius of | r₁ | mm | 0.114 | | | | | |
| transparent dielectric | | | | | | | | |
| Length of transparent | H | mm | 1.920 | 3.840 | 7.680 | 15.360 | 23.040 | 38.400 |
| dielectric | | | | | | | | |
| Ratio of length of | H/(n₁ · L₀₁) | | 0.032 | 0.064 | 0.127 | 0.255 | 0.382 | 0.637 |
| transparent dielectric | | | | | | | | |
| array to L₀₁, divided | | | | | | | | |
| by refractive index | | | | | | | | |

TABLE 5

| Item | Symbol | Unit | α-b-1 | α-b-2 | α-b-3 | α-b-4 | α-b-5 | α-b-6 |
|---|---|---|---|---|---|---|---|---|
| Rod lens array to be | | | Rod lens array α | | | | | |
| arranged | | | | | | | | |
| Array pitch of | P₁ | mm | 0.6 × P₀ | | | | | |
| transparent dielectric | | | | | | | | |
| Number of rows of | m | | 2 | | | | | |
| transparent dielectric | | | | | | | | |
| array | | | | | | | | |
| Refractive index of | n₁ | mm | 1.600 | | | | | |
| transparent dielectric | | | | | | | | |
| Diameter of | D₁ | mm | 0.360 | | | | | |
| transparent dielectric | | | | | | | | |
| Effective radius of | r₁ | mm | 0.171 | | | | | |
| transparent dielectric | | | | | | | | |
| Length of transparent | H | mm | 5.760 | 11.520 | 17.280 | 23.040 | 34.560 | 46.080 |
| dielectric | | | | | | | | |
| Ratio of length of | H/(n₁ · L₀₁₎ | | 0.095 | 0.191 | 0.286 | 0.382 | 0.573 | 0.764 |
| transparent dielectric | | | | | | | | |
| array to L₀₁, divided | | | | | | | | |
| by refractive index | | | | | | | | |

TABLE 6

| Item | Symbol | Unit | α-c-1 | α-c-2 | α-c-3 | α-c-4 | α-c-5 |
|---|---|---|---|---|---|---|---|
| Rod lens array to be | | | Rod lens array α | | | | |
| arranged | | | | | | | |
| Array pitch of | P₁ | mm | 0.8 × P₀ | | | | |
| transparent dielectric | | | | | | | |
| Number of rows of | m | | 2 | | | | |
| transparent dielectric | | | | | | | |
| array | | | | | | | |
| Refractive index of | n₁ | mm | 1.600 | | | | |
| transparent dielectric | | | | | | | |
| Diameter of | D₁ | mm | 0.480 | | | | |
| transparent dielectric | | | | | | | |
| Effective radius of | r₁ | mm | 0.228 | | | | |
| transparent dielectric | | | | | | | |
| Length of transparent | H | mm | 7.680 | 15.360 | 23.040 | 30.720 | 46.080 |
| dielectric | | | | | | | |
| Ratio of length of | H/(n₁ · L₀₁) | | 0.127 | 0.255 | 0.382 | 0.509 | 0.764 |
| transparent dielectric | | | | | | | |
| array to L₀₁, divided | | | | | | | |
| by refractive index | | | | | | | |

TABLE 7

| Item | Symbol | Unit | β-a-1 | β-a-2 | β-a-3 | β-a-4 | β-a-5 | β-a-6 |
|---|---|---|---|---|---|---|---|---|
| Rod lens array to be | | | Rod lens array β | | | | | |
| arranged | | | | | | | | |
| Array pitch of | P₁ | mm | 0.4 × P₀ | | | | | |
| transparent dielectric | | | | | | | | |
| Number of rows of | m | | 2 | | | | | |
| transparent dielectric | | | | | | | | |
| array | | | | | | | | |
| Refractive index of | n₁ | mm | 1.600 | | | | | |
| transparent dielectric | | | | | | | | |
| Diameter of | D₁ | mm | 0.240 | | | | | |
| transparent dielectric | | | | | | | | |
| Effective radius of | r₁ | mm | 0.114 | | | | | |
| transparent dielectric | | | | | | | | |
| Length of transparent | H | mm | 1.920 | 3.840 | 7.680 | 11.520 | 15.360 | 19.200 |
| dielectric | | | | | | | | |
| Ratio of length of | H/(n₁ · L₀₁) | | 0.076 | 0.153 | 0.306 | 0.458 | 0.611 | 0.764 |
| transparent dielectric | | | | | | | | |
| array to L₀₁, divided | | | | | | | | |
| by refractive index | | | | | | | | |

TABLE 8

| Item | Symbol | Unit | β-b-1 | β-b-2 | β-b-3 | β-b-4 | β-b-5 |
|---|---|---|---|---|---|---|---|
| Rod lens array to be | | | Rod lens array β | | | | |
| arranged | | | | | | | |
| Array pitch of | P₁ | mm | 0.6 × P₀ | | | | |
| transparent dielectric | | | | | | | |
| Number of rows of | m | | 2 | | | | |
| transparent dielectric | | | | | | | |
| array | | | | | | | |
| Refractive index of | n₁ | mm | 1.600 | | | | |
| transparent dielectric | | | | | | | |
| Diameter of | D₁ | mm | 0.360 | | | | |
| transparent dielectric | | | | | | | |
| Effective radius of | r₁ | mm | 0.171 | | | | |
| transparent dielectric | | | | | | | |
| Length of transparent | H | mm | 2.880 | 5.760 | 8.641 | 11.521 | 17.281 |
| dielectric | | | | | | | |
| Ratio of length of | H/(n₁ · L₀₁) | | 0.115 | 0.229 | 0.344 | 0.458 | 0.688 |
| transparent dielectric | | | | | | | |
| array to L₀₁, divided | | | | | | | |
| by refractive index | | | | | | | |

TABLE 9

| | | | β-c- | β-c- | β-c- | β-c- |
|---|---|---|---|---|---|---|
| Item | Symbol | Unit | 1 | 2 | 3 | 4 |
| Rod lens array to be | | | Rod lens array β | | | |
| arranged | | | | | | |
| Array pitch of | P₁ | mm | 0.8 × P₀ | | | |
| transparent dielectric | | | | | | |
| Number of rows of | m | | 2 | | | |
| transparent dielectric | | | | | | |
| array | | | | | | |
| Refractive index of | n₁ | mm | 1.600 | | | |
| transparent dielectric | | | | | | |
| Diameter of | D₁ | mm | 0.480 | | | |
| transparent dielectric | | | | | | |
| Effective radius of | r₁ | mm | 0.228 | | | |
| transparent dielectric | | | | | | |
| Length of transparent | H | mm | 3.841 | 7.681 | 11.522 | 19.203 |
| dielectric | | | | | | |
| Ratio of length of | H/(n₁ · | | 0.153 | 0.306 | 0.458 | 0.764 |
| transparent dielectric | L₀₁) | | | | | |
| array to L₀₁, divided | | | | | | |
| by refractive index | | | | | | |

TABLE 10

| Item | Symbol | Unit | γ-a-1 | γ-a-2 | γ-a-3 | γ-a-4 | γ-a-5 | γ-a-6 | γ-a-7 | γ-a-8 |
|---|---|---|---|---|---|---|---|---|---|---|
| Rod lens array to | | | Rod lens array γ | | | | | | | |
| be arranged | | | | | | | | | | |
| Array pitch of | P₁ | mm | 0.4 × P₀ | | | | | | | |
| transparent | | | | | | | | | | |
| dielectric | | | | | | | | | | |
| Number of rows | m | | 2 | | | | | | | |
| of transparent | | | | | | | | | | |
| dielectric array | | | | | | | | | | |
| Refractive index | n₁ | mm | 1.600 | | | | | | | |
| of transparent | | | | | | | | | | |
| dielectric | | | | | | | | | | |
| Diameter of | D₁ | mm | 0.240 | | | | | | | |
| transparent | | | | | | | | | | |
| dielectric | | | | | | | | | | |
| Effective radius | r₁ | mm | 0.114 | | | | | | | |
| of transparent | | | | | | | | | | |
| dielectric | | | | | | | | | | |
| Length of | H | mm | 0.768 | 1.152 | 1.536 | 3.072 | 3.839 | 4.607 | 6.143 | 9.215 |
| transparent | | | | | | | | | | |
| dielectric | | | | | | | | | | |
| Ratio of length of | H/(n₁ · L₀₁) | | 0.064 | 0.095 | 0.127 | 0.255 | 0.318 | 0.382 | 0.509 | 0.764 |
| transparent | | | | | | | | | | |
| dielectric array to | | | | | | | | | | |
| L₀₁, divided by | | | | | | | | | | |
| refractive index | | | | | | | | | | |

TABLE 11

| Item | Symbol | Unit | γ-b-1 | γ-b-2 | γ-b-3 | γ-b-4 | γ-b-5 | γ-b-6 | γ-b-7 |
|---|---|---|---|---|---|---|---|---|---|
| Rod lens array to be | | | Rod lens array γ | | | | | | |
| arranged | | | | | | | | | |
| Array pitch of transparent | P₁ | mm | 0.6 × P₀ | | | | | | |
| dielectric | | | | | | | | | |
| Number of rows of | m | | 2 | | | | | | |
| transparent dielectric | | | | | | | | | |
| array | | | | | | | | | |
| Refractive index of | n₁ | mm | 1.600 | | | | | | |
| transparent dielectric | | | | | | | | | |
| Diameter of transparent | D₁ | mm | 0.360 | | | | | | |
| dielectric | | | | | | | | | |
| Effective radius of | r₁ | mm | 0.171 | | | | | | |
| transparent dielectric | | | | | | | | | |
| Length of transparent | H | mm | 1.152 | 2.304 | 3.457 | 4.609 | 5.761 | 7.489 | 9.218 |
| dielectric | | | | | | | | | |
| Ratio of length of | H/(n₁ · L₀₁) | | 0.096 | 0.191 | 0.287 | 0.382 | 0.478 | 0.621 | 0.764 |
| transparent dielectric | | | | | | | | | |
| array to L₀₁, divided by | | | | | | | | | |
| refractive index | | | | | | | | | |

TABLE 12

| Item | Symbol | Unit | γ-c-1 | γ-c-2 | γ-c-3 | γ-c-4 | γ-c-5 | γ-c-6 | γ-c-7 |
|---|---|---|---|---|---|---|---|---|---|
| Rod lens array to be | | | Rod lens array γ | | | | | | |
| arranged | | | | | | | | | |
| Array pitch of | P₁ | mm | 0.8 × P₀ | | | | | | |
| transparent dielectric | | | | | | | | | |
| Number of rows of | m | | 2 | | | | | | |
| transparent dielectric | | | | | | | | | |
| array | | | | | | | | | |
| Refractive index of | n₁ | mm | 1.600 | | | | | | |
| transparent dielectric | | | | | | | | | |
| Diameter of | D₁ | mm | 0.480 | | | | | | |
| transparent dielectric | | | | | | | | | |
| Effective radius of | r₁ | mm | 0.228 | | | | | | |
| transparent dielectric | | | | | | | | | |
| Length of transparent | H | mm | 1.536 | 2.304 | 3.072 | 4.607 | 6.143 | 7.679 | 9.215 |
| dielectric | | | | | | | | | |
| Ratio of length of | H/(n₁ · L₀₁) | | 0.127 | 0.191 | 0.255 | 0.382 | 0.509 | 0.637 | 0.764 |
| transparent dielectric | | | | | | | | | |
| array to L₀₁, divided | | | | | | | | | |
| by refractive index | | | | | | | | | |

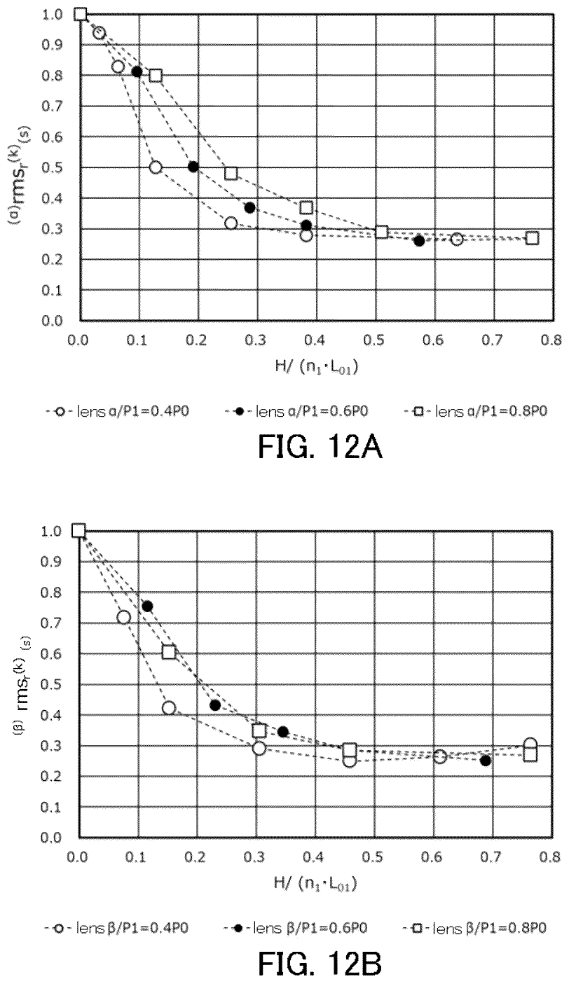

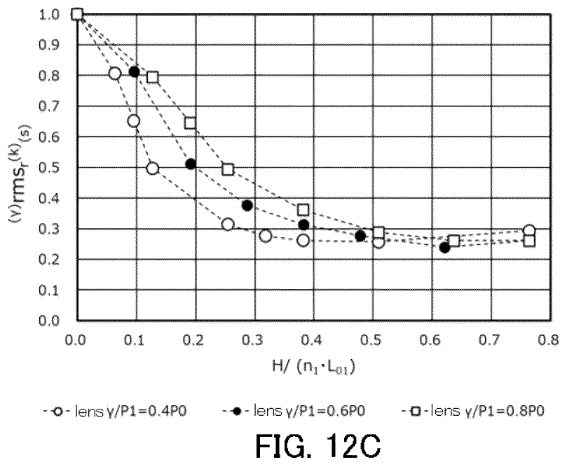

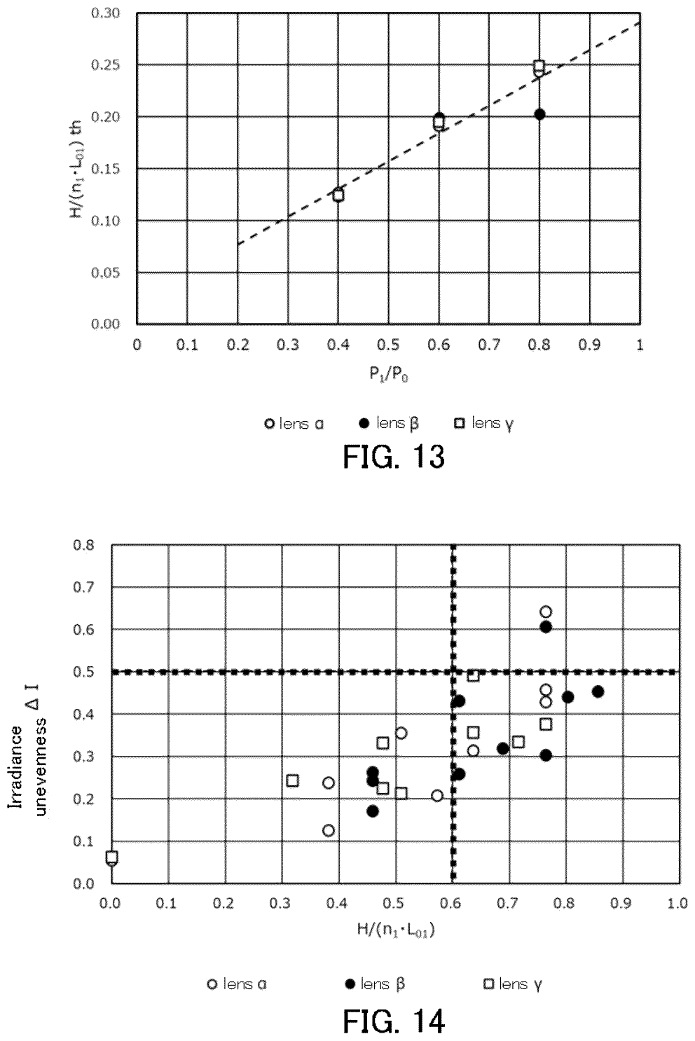

FIG. 12A is a graph showing a relation between a ratio ^{(h)}rmsᵣ^{(k)}₍ₛ₎ of a ray aberration rms (where the subscripts h, k, and s have the same meaning as described above, which will be omitted hereinafter) and H/(n₁·L₀₁) in an optical system configured with a rod lens array α and a transparent dielectric array belonging to the transparent dielectric array groups a to c. FIG. 12B is a graph showing a relation between a ratio ^{(h)}rmsᵣ^{(k)}₍ₛ₎ of a ray aberration rms and H/(n₁·L₀₁) in an optical system configured with a rod lens array β and a transparent dielectric array belonging to the transparent dielectric array groups a to c. FIG. 12C is a graph showing a relation between a ratio ^{(h)}rmsᵣ^{(k)}₍ₛ₎ of a ray aberration rms and H/(n₁·L₀₁) in an optical system configured with a rod lens array γ and a transparent dielectric array belonging to the transparent dielectric array groups a to c. As shown in FIG. 10C, L₀₁ is the distance in the z direction between the rod lens array and the object plane OP when the object plane OP at the position A and the image plane IP form an erecting equal-magnification system. Table 13 shows a value H/(n₁·L₀₁)th of H/(n₁·L₀₁) for which the ratio ^{(h)}rmsᵣ^{(k)}₍ₛ₎ is 0.5 or less, as determined from FIG. 12A to FIG. 12C. In addition, FIG. 13 shows a relation between the value of P₁/P₀ for each optical system and a value of H/(n₁·L₀₁)th at which the ratio ^{(h)}rmsᵣ^{(k)}₍ₛ₎ is 0.5 or less, along with the approximate straight line drawn in broken lines. This relationship indicates that the value H/(n₁·L₀₁)th increases almost in proportion to P₁/P₀, regardless of the type of lens. In other words, it will be understood, from a relation between the value of P₁/P₀ shown in FIG. 11 and the value of H/(n₁·L₀₁)th at which the ratio ^{(h)}rmsᵣ^{(k)}₍ₛ₎ is 0.5 or less, that in an optical device including a lens array and a transparent dielectric array, in order to further improve the depth of field, it is advantageous for a requirement of the following formula (6) to be satisfied.

$$H / ( {n}_{1} \cdot {L}_{01} ) > 0.27 ( {P}_{1} / {P}_{0} ) + 0.023 \qquad Formula ( 6 )$$

TABLE 13

| | P₁/P₀ | H/(n₁ · L₀₁)ₜₕ |
|---|---|---|
| Rod lens α | 0.4 | 0.127 |
| | 0.6 | 0.191 |
| | 0.8 | 0.243 |
| Rod lens β | 0.4 | 0.124 |
| | 0.6 | 0.199 |
| | 0.8 | 0.203 |
| Rod lens γ | 0.4 | 0.124 |
| | 0.6 | 0.195 |
| | 0.8 | 0.250 |

As described above, a composite image is formed on the image plane by overlapping the images formed by the neighboring single lenses, including the adjacent single lenses, in the lens array. Since the images formed by the single lenses each have a light distribution such as the cosine-fourth-law, periodic unevenness in illumination can occur in the composite image. The unevenness in illumination can be corrected, for example, by gain correction of the image signal from the image sensor. However, if this unevenness in illumination is too large, for example, larger than 0.5 of the average illumination, the unevenness can cause problems in practical use, such as a significant decrease in the contrast of the image of the object being examined, resulting in streaks and other defects.

Therefore, an optical simulation to determine the irradiance on the image plane was performed in an optical device or optical system equipped with a rod lens array and a transparent dielectric array. For calculation of irradiance, lighting analysis software Trace Pro Standard 7 by Lambda Research Corporation in the United States was used. The optical simulation conditions employed in the optical system are shown in FIG. 10C and FIG. 10D. The rod lens arrays used were the rod lens arrays α, β, and γ shown in Table 3, and the transparent dielectric arrays used were the transparent dielectric arrays of three groups a′, b′, and c′ shown in Table 14 to Table 22. These were arranged to configure the optical system. In addition, the arrangement of the object plane, the rod lens array, the transparent dielectric array, and the image plane was determined such that the system would be an erecting equal-magnification image system with the highest image resolution in the optical simulation. The position of the object plane at this time is determined as A. The position A is the regular arrangement.

TABLE 14

| Item | Symbol | Unit | α-a′-1 | α-a′-2 | α-a′-3 |
|---|---|---|---|---|---|
| Rod lens array to be | | | Rod lens array α | | |
| arranged | | | | | |
| Array pitch of | P₁ | mm | 0.4 × P₀ | | |
| transparent dielectric | | | | | |
| Number of rows of | m | | 2 | | |
| transparent dielectric | | | | | |
| array | | | | | |
| Refractive index of | n₁ | mm | 1.600 | | |
| transparent dielectric | | | | | |
| Diameter of transparent | D₁ | mm | 0.240 | | |
| dielectric | | | | | |
| Effective radius of | r₁ | mm | 0.114 | | |
| transparent dielectric | | | | | |
| Length of transparent | H | mm | 23.040 | 30.720 | 46.080 |
| dielectric | | | | | |
| Ratio of length of | H/(n₁ · | | 0.382 | 0.509 | 0.764 |
| transparent dielectric | L₀₁) | | | | |
| array to L₀₁, divided by | | | | | |
| refractive index | | | | | |

TABLE 15

| Item | Symbol | Unit | α-b′-1 | α-b′-2 |
|---|---|---|---|---|
| Rod lens array to be | | | Rod lens array α | |
| arranged | | | | |
| Array pitch of | P₁ | mm | 0.6 × P₀ | |
| transparent dielectric | | | | |
| Number of rows of | m | | 2 | |
| transparent dielectric | | | | |
| array | | | | |
| Refractive index of | n₁ | mm | 1.600 | |
| transparent dielectric | | | | |
| Diameter of transparent | D₁ | mm | 0.360 | |
| dielectric | | | | |
| Effective radius of | r₁ | mm | 0.171 | |
| transparent dielectric | | | | |
| Length of transparent | H | mm | 34.560 | 46.080 |
| dielectric | | | | |
| Ratio of length of | H/(n₁ · L₀₁) | | 0.573 | 0.764 |
| transparent dielectric | | | | |
| array to L₀₁, divided by | | | | |
| refractive index | | | | |

TABLE 16

| Item | Symbol | Unit | α-c′-1 | α-c′-2 | α-c′-3 |
|---|---|---|---|---|---|
| Rod lens array to be | | | Rod lens array α | | |
| arranged | | | | | |
| Array pitch of | P₁ | mm | 0.8 × P₀ | | |
| transparent dielectric | | | | | |
| Number of rows of | m | | 2 | | |
| transparent dielectric | | | | | |
| array | | | | | |
| Refractive index of | n₁ | mm | 1.600 | | |
| transparent dielectric | | | | | |
| Diameter of transparent | D₁ | mm | 0.480 | | |
| dielectric | | | | | |
| Effective radius of | r₁ | mm | 0.228 | | |
| transparent dielectric | | | | | |
| Length of transparent | H | mm | 23.040 | 38.400 | 46.080 |
| dielectric | | | | | |
| Ratio of length of | H/(n₁ · | | 0.382 | 0.637 | 0.764 |
| transparent dielectric | L₀₁) | | | | |
| array to L₀₁, divided by | | | | | |
| refractive index | | | | | |

TABLE 17

| Item | Symbol | Unit | β-a′-1 | β-a′-2 | β-a′-3 |
|---|---|---|---|---|---|
| Rod lens array to be | | | Rod lens array β | | |
| arranged | | | | | |
| Array pitch of | P₁ | mm | 0.4 × P₀ | | |
| transparent dielectric | | | | | |
| Number of rows of | m | | 2 | | |
| transparent dielectric | | | | | |
| array | | | | | |
| Refractive index of | n₁ | mm | 1.600 | | |
| transparent dielectric | | | | | |
| Diameter of transparent | D₁ | mm | 0.240 | | |
| dielectric | | | | | |
| Effective radius of | r₁ | mm | 0.114 | | |
| transparent dielectric | | | | | |
| Length of transparent | H | mm | 11.520 | 15.360 | 19.200 |
| dielectric | | | | | |
| Ratio of length of | H/(n₁ · | | 0.458 | 0.611 | 0.764 |
| transparent dielectric | L₀₁) | | | | |
| array to L₀₁, divided by | | | | | |
| refractive index | | | | | |

TABLE 18

| Item | Symbol | Unit | β-b′-1 | β-b′-2 | β-b′-3 |
|---|---|---|---|---|---|
| Rod lens array to be | | | Rod lens array β | | |
| arranged | | | | | |
| Array pitch of | P₁ | mm | 0.6 × P₀ | | |
| transparent dielectric | | | | | |
| Number of rows of | m | | 2 | | |
| transparent dielectric | | | | | |
| array | | | | | |
| Refractive index of | n₁ | mm | 1.600 | | |
| transparent dielectric | | | | | |
| Diameter of transparent | D₁ | mm | 0.360 | | |
| dielectric | | | | | |
| Effective radius of | r₁ | mm | 0.171 | | |
| transparent dielectric | | | | | |
| Length of transparent | H | mm | 11.520 | 17.280 | 20.160 |
| dielectric | | | | | |
| Ratio of length of | H/(n₁ · | | 0.458 | 0.688 | 0.802 |
| transparent dielectric | L₀₁) | | | | |
| array to L₀₁, divided by | | | | | |
| refractive index | | | | | |

TABLE 19

| Item | Symbol | Unit | β-c′-1 | β-c′-2 | β-c′-3 | β-c′-4 |
|---|---|---|---|---|---|---|
| Rod lens array to be | | | Rod lens array β | | | |
| arranged | | | | | | |
| Array pitch of | P₁ | mm | 0.8 × P₀ | | | |
| transparent dielectric | | | | | | |
| Number of rows of | m | | 2 | | | |
| transparent dielectric | | | | | | |
| array | | | | | | |
| Refractive index of | n₁ | mm | 1.600 | | | |
| transparent dielectric | | | | | | |
| Diameter of transparent | D₁ | mm | 0.480 | | | |
| dielectric | | | | | | |
| Effective radius of | r₁ | mm | 0.228 | | | |
| transparent dielectric | | | | | | |
| Length of transparent | H | mm | 11.520 | 15.360 | 19.200 | 21.504 |
| dielectric | | | | | | |
| Ratio of length of | H/(n₁ · L₀₁) | | 0.458 | 0.611 | 0.764 | 0.856 |
| transparent dielectric | | | | | | |
| array to L₀₁, divided by | | | | | | |
| refractive index | | | | | | |

TABLE 20

| Item | Symbol | Unit | γ-a-1 | γ-a-2 | γ-a-3 |
|---|---|---|---|---|---|
| Rod lens array to be | | | Rod lens array γ | | |
| arranged | | | | | |
| Array pitch of | P₁ | mm | 0.4 × P₀ | | |
| transparent dielectric | | | | | |
| Number of rows of | m | | 2 | | |
| transparent dielectric | | | | | |
| array | | | | | |
| Refractive index of | n₁ | mm | 1.600 | | |
| transparent dielectric | | | | | |
| Diameter of transparent | D₁ | mm | 0.240 | | |
| dielectric | | | | | |
| Effective radius of | r₁ | mm | 0.114 | | |
| transparent dielectric | | | | | |
| Length of transparent | H | mm | 3.840 | 5.760 | 7.680 |
| dielectric | | | | | |
| Ratio of length of | H/(n₁ · L₀₁) | | 0.318 | 0.477 | 0.637 |
| transparent dielectric | | | | | |
| array to L₀₁, divided by | | | | | |
| refractive index | | | | | |

TABLE 21

| Item | Symbol | Unit | γ-b-1 | γ-b-2 |
|---|---|---|---|---|
| Rod lens array to be | | | Rod lens array γ | |
| arranged | | | | |
| Array pitch of | P₁ | mm | 0.6 × P₀ | |
| transparent dielectric | | | | |
| Number of rows of | m | | 2 | |
| transparent dielectric | | | | |
| array | | | | |
| Refractive index of | n₁ | mm | 1.600 | |
| transparent dielectric | | | | |
| Diameter of transparent | D₁ | mm | 0.360 | |
| dielectric | | | | |
| Effective radius of | r₁ | mm | 0.171 | |
| transparent dielectric | | | | |
| Length of transparent | H | mm | 5.760 | 8.640 |
| dielectric | | | | |
| Ratio of length of | H/(n₁ · L₀₁) | | 0.477 | 0.716 |
| transparent dielectric | | | | |
| array to L₀₁, divided by | | | | |
| refractive index | | | | |

TABLE 22

| Item | Symbol | Unit | γ-c-1 | γ-c-2 | γ-c-3 |
|---|---|---|---|---|---|
| Rod lens array to be | | | Rod lens array γ | | |
| arranged | | | | | |
| Array pitch of | P₁ | mm | 0.8 × P₀ | | |
| transparent dielectric | | | | | |
| Number of rows of | m | | 2 | | |
| transparent dielectric | | | | | |
| array | | | | | |
| Refractive index of | n₁ | mm | 1.600 | | |
| transparent dielectric | | | | | |
| Diameter of transparent | D₁ | mm | 0.480 | | |
| dielectric | | | | | |
| Effective radius of | r₁ | mm | 0.228 | | |
| transparent dielectric | | | | | |
| Length of transparent | H | mm | 6.144 | 7.680 | 9.216 |
| dielectric | | | | | |
| Ratio of length of | H/(n₁ · L₀₁) | | 0.509 | 0.637 | 0.764 |
| transparent dielectric | | | | | |
| array to L₀₁, divided by | | | | | |
| refractive index | | | | | |

In the optical simulation, a surface light source for emitting uniform light from the object plane at the position A was arranged, thereby calculating the unevenness in illuminance on the image plane of each optical system. The surface light source used in the optical simulation was provided to emit light with a wavelength of 570 nm and a Lambertian distribution, and 10 million beams were traced. Due to the periodicity of the rod lens array and the transparent dielectric array, the irradiance also tends to be periodic in the main-scanning direction (x direction). For applications such as image sensors, it is better for the irradiance detected by the light receiving element array to be constant in the main-scanning direction. In the case where the irradiance has variations or periodic fluctuations in the main-scanning direction, the image sensor will acquire images with variations and fluctuations in shade and brightness, which is regarded as inappropriate. Therefore, simulations were performed for each optical system to obtain the irradiance distribution in the main-scanning direction and to evaluate the irradiance unevenness.

FIG. 14 shows the irradiance unevenness ΔI. This irradiance unevenness ΔI was calculated within the range of x=0 [mm] to x=100 [mm] after determining the regular arrangement for each of the optical systems configured by combining three types of rod lens arrays, namely, rod lens arrays α, β, and γ, with the transparent dielectric array of group a′ (P₁=0.4×P₀), the transparent dielectric array of group b′ (P₁=0.6×P₀), and the transparent dielectric array of group c′ (P₁=0.8×P₀) shown in Table 4. In FIG. 14, the horizontal axis is H/(n₁·L₀₁), and the vertical axis is the irradiance unevenness ΔI. The irradiance unevenness ΔI was calculated using the following Formula (7), by calculating the maximum irradiance Iₘₐₓ and minimum irradiance Iₘᵢₙ within the range in the main-scanning direction (x direction).

$$Δ I = 2 \times ( {I}_{max} - {I}_{min} ) / ( {I}_{max} + {I}_{min} ) \qquad Formula ( 7 )$$

FIG. 14 shows the relation between the irradiance unevenness ΔI and the parameter H/(n₁·L₀₁). As shown in FIG. 14, it is desirable that the value of the irradiance unevenness ΔI is smaller. However, in the relation between the irradiance unevenness ΔI and H/(n₁·L₀₁), ΔI showed a tendency to increase with increasing H/(n₁·L₀₁) while having a band-like width, regardless of the lens type. It is inferred that, when H/(n₁·L₀₁) is large, the effect of limiting the aperture of the rod lens is enhanced, and the angle of the beam radiated from the transparent dielectric array to the image plane becomes small, and the overlap of the irradiance distribution of each transparent dielectric of the transparent dielectric array becomes poor.

It is further inferred that, from the relation shown in FIG. 14, when H/(n₁·L₀₁) is greater than 0.6, the irradiance unevenness ΔI in the optical system configured by arranging a rod lens array and a transparent dielectric array exceeds 0.5, depending on the set of the rod lens and the transparent dielectric array. According to the results of this consideration, it is understood that in order to reduce the unevenness in illuminance in an optical device or an optical system each including a rod lens array and a transparent dielectric array, it is desirable that the requirement H/(n₁·L₀₁)≤0.6 is satisfied. Furthermore, when the value of H/(n₁·L₀₁) is 0.46 or less, the irradiance unevenness ΔI is 0.3 or less, which is more desirable.

In the optical device 1a, the irradiance unevenness ΔI is, for example, 0.5 or less. The irradiance unevenness ΔI is preferably 0.4 or less, and more preferably 0.3 or less.

In the optical device 1a, there may be an air layer or a vacuum layer between the lens array 10 and the transparent dielectric array 20. There may be a transparent adhesive filling the gap between the lens array 10 and the transparent dielectric array 20, or there may be a resin as a transparent pressure-sensitive adhesive layer or a transparent adhesive layer, such as Optical Clear Adhesive (OCA). In the case where there is a resin between the lens array 10 and the transparent dielectric array 20, it is desirable that the refractive index of the resin is close to the refractive index of the lens 11 of the lens array 10 and to the refractive index of the transparent dielectric 21 of the transparent dielectric array 20, because the loss of light due to interface reflection can be reduced.

Application of the optical device 1a is not limited to specific applications. The optical device 1a can be used in optical products or optical equipment, such as image sensors, scanners, printers, line sensor cameras, copiers, facsimiles, multifunction devices (devices that include functions such as copiers and printers), appearance inspection devices, and endoscopes.

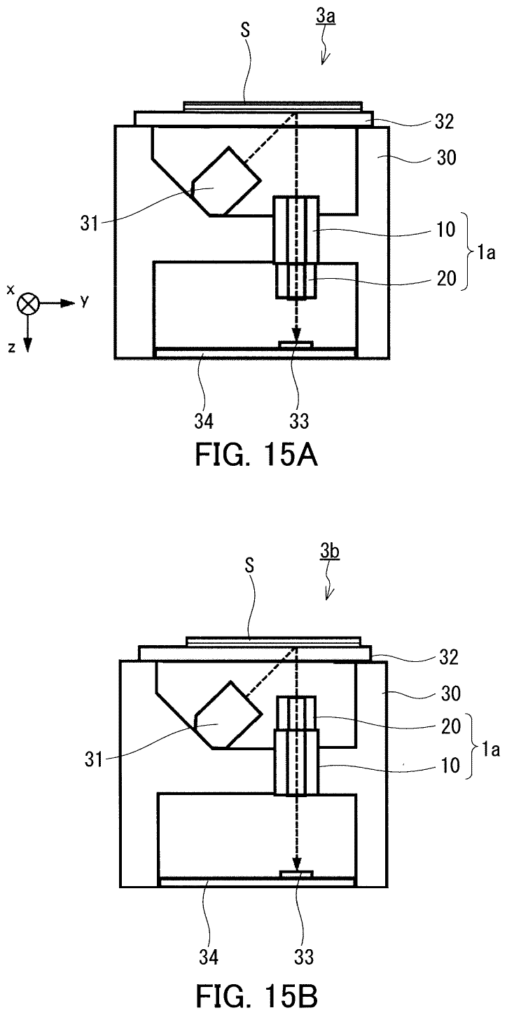

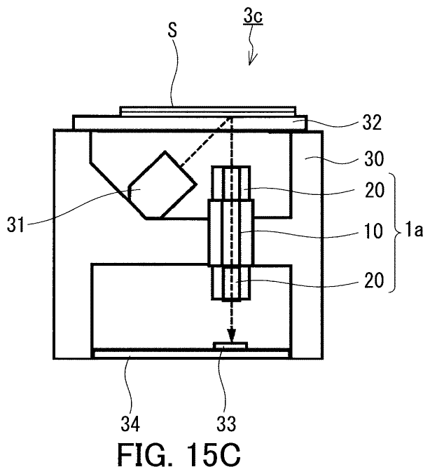

FIG. 15A is a diagram showing an example of an image sensor. As shown in FIG. 15A, an image sensor 3a includes an optical device 1a. The image sensor 3a is, for example, a CIS. In the image sensor 3a, the optical axis of the lens 11 of the lens array 10 and the central axis of the transparent dielectric 21 of the transparent dielectric array 20 of the optical device 1a extend in the z-axis direction. A plurality of lenses 11 in the lens array 10 are arrayed along the x-axis direction (main-scanning direction). The dimensions of the image sensor 3a or the parts included in the image sensor 3a in the x-axis direction may be larger than the dimensions in the y-axis direction orthogonal to the x-axis and the z-axis.

As shown in FIG. 15A, the image sensor 3a includes a housing 30, a linear illuminator 31, a document platen 32, a light receiving element array 33, and an electric circuit board 34. The optical device 1a, the linear illuminator 31, the light receiving element array 33, and the electric circuit board 34 are arranged inside the housing 30.

The document platen 32 is made of glass and is arranged to cover the opening of the housing 30. The linear illuminator 31, for example, emits illuminating light that is substantially uniform in the x-axis direction to illuminate an object S, such as a document. A part of the light reflected on the surface of the object S passes through the lens array 10 and the transparent dielectric array 20 in this order, and reaches the PD of the light receiving element array 33 or avalanche photodiode (APD) and other light receiving elements, so that an image of the information on the surface of the object S is formed onto a light receiving plane of the light receiving element. In the image sensor 3a, the optical device 1a is produced such that the surface of the object corresponds to the object plane OP and the light receiving plane of the light receiving element corresponds to the image plane IP, so that an erecting equal-magnification array is arranged in the optical device 1a. Since the image sensor 3a itself is scanned in the y-axis direction, two-dimensional information of the object S is acquired.

In the image sensor 3a, the transparent dielectric array 20 is arranged to face the light-emitting surface of the lens array 10. The lens array 10 and the transparent dielectric array 20 may be separately incorporated into the internal structure of the housing 30. Alternatively, the lens array 10 and the transparent dielectric array 20 may be integrated in advance by adhesion or the like, and then incorporated into the housing 30. For this reason, the optical device 1a may be configured such that the lens array 10 and transparent dielectric array 20 are separately incorporated, or it may have a configuration where the lens array 10 and the transparent dielectric array 20 are integrated.

FIG. 15B shows another example of an image sensor, and FIG. 15C shows yet another example of an image sensor. The image sensors 3b and 3c shown in FIG. 15B and FIG. 15C, respectively, are configured in the same way as the image sensor 3a, except for the parts that are specifically explained. The components of the image sensors 3b and 3c that are identical or corresponding to the components of the image sensor 3a are given the same symbols, and the detailed explanations will be omitted. The description for the image sensor 3a also applies to image sensors 3b and 3c, unless there is a technical contradiction.

As shown in FIG. 15B, in an image sensor 3b, a transparent dielectric array 20 is arranged to face the light-incident surface of a lens array 10.

As shown in FIG. 15C, in an image sensor 3c, transparent dielectric arrays 20 are arranged each to face the light-emitting surface of the lens array 10 and further the light-incident surface of a lens array 10.

1. An optical device comprising:
a lens array comprising a plurality of lenses, where the lenses are arrayed such that optical axes of the lenses are substantially parallel to each other; and
a transparent dielectric array comprising a plurality of transparent dielectrics, where the transparent dielectrics are arrayed such that central axes of the transparent dielectrics are substantially parallel to each other,
wherein the lens array and the transparent dielectric array are arranged such that the optical axes and the central axes are substantially parallel to each other and an end surface of the lens array faces an end surface of the transparent dielectric array.

2. The optical device according to claim 1, wherein
the lenses each is a rod lens having a refractive index distribution in a radial direction.

3. The optical device according to claim 1, wherein
an array pitch P₀ of the lens array and an array pitch P₁ of the transparent dielectric array satisfy a first requirement 0.3×P₀≤P₁≤0.8×P₀.

4. The optical device according to claim 3, wherein
a refractive index n₁ of the transparent dielectric array and a length H [mm] of the transparent dielectric array satisfy a second requirement H/(n₁·L₀₁)>0.27×(P₁/P₀)+0.023, and
in the second requirement, L₀₁ is a distance [mm] between the lens array and an object plane when an erecting equal-magnification image of the object plane is formed with the highest resolution.

5. The optical device according to claim 1, wherein
an irradiance unevenness ΔI is 0.5 or less,
the irradiance unevenness ΔI satisfies a relation ΔI=2×(Iₘₐₓ−Iₘᵢₙ)/(Iₘₐₓ+Iₘᵢₙ), and
in the relation, Iₘₐₓ is the maximum value of irradiance in a main-scanning direction of the optical device, and Iₘᵢₙ is the minimum value of the irradiance in the main-scanning direction of the optical device.

6. The optical device according to claim 1, wherein
the refractive index n₁ of the transparent dielectric array and the length H [mm] of the transparent dielectric array satisfy a third requirement H/(n₁·L₀₁)≤0.6, and
in the third requirement, L₀₁ is a distance [mm] between the lens array and the object plane when the erecting equal-magnification image of the object plane is formed with the highest resolution.

7. The optical device according to claim 2, wherein
the optical axes of the lenses of the lens array and the central axes of the transparent dielectrics of the transparent dielectric array are substantially aligned,
a fourth requirement tan θ₀·H/n₁>P₁/2 is satisfied,
n₁ is a refractive index of the transparent dielectric,
H is a length [mm] of the transparent dielectric in a direction parallel to the central axis,
P₁ is a distance [mm] between the central axes of the adjacent transparent dielectrics in the transparent dielectric array,
θ₀ is an aperture angle of the rod lens,
when the refractive index distribution of the rod lens is expressed as n(r)²=n₀²·{1−(g·r)²}, θ₀ satisfies a relation sin θ₀=n₀·g·r₀,
r is a distance [mm] from the optical axis of the rod lens in the radial direction,
n(r) is a refractive index of the rod lens at the distance r,
n₀ is a refractive index at the optical axis of the rod lens,
g is a refractive index distribution constant of the rod lens, and
r₀ is an effective radius [mm] of the rod lens.

8. An image sensor comprising the optical device according to any claim 1.

9. A method for manufacturing the optical device according to claim 1, comprising:
arranging the transparent dielectric array and the lens array such that the central axes of the transparent dielectrics are substantially parallel to the optical axes of the lenses and the end surface of the transparent dielectric array faces the end surface of the lens array substantially in parallel.

10. The method according to claim 9, comprising:
arraying a plurality of glass rods obtained by a down-draw process such that central axes of the glass rods are substantially parallel to each other; and
forming a pair of planes substantially perpendicular to the central axes of the glass rods to obtain the transparent dielectrics.
